(19) United States
(12) Patent Application Publication
(10) Pub. No.: US 2025/0072257 A1
(43) Pub. Date: Feb. 27, 2025

(54) ELECTRONIC PANEL AND ELECTRONIC DEVICE

(71) Applicant: InnoLux Corporation, Miao-Li County (TW)

(72) Inventors: Chandra Lius, Miao-Li County (TW); Kuan-Feng Lee, Miao-Li County (TW)

(73) Assignee: InnoLux Corporation, Miao-Li County (TW)

(21) Appl. No.: 18/780,465

(22) Filed: Jul. 22, 2024

(30) Foreign Application Priority Data
Aug. 22, 2023 (CN) 202311056326.1

(51) Int. Cl. H10K 59/38; H10K 39/34

(52) U.S. Cl. CPC H10K 59/38; H10K 39/34

(57) ABSTRACT

An electronic panel including a substrate, a first semiconductor element and a first color conversion element is provided by the present disclosure. The substrate has a functional region capable of allowing a light to pass through. The first semiconductor element is disposed on the functional region, wherein the first semiconductor element includes a first electrode, a first semiconductor layer disposed on the first electrode, and a second electrode disposed on the first semiconductor layer. The first color conversion element is disposed on the first semiconductor element and overlapped with the first semiconductor layer. In a top view of the electronic panel, a center of the first color conversion element is deviated from a center of the first semiconductor layer.

### BACKGROUND OF THE DISCLOSURE

### 1. Field of the Disclosure

The present disclosure relates to an electronic panel and an electronic device including the electronic panel, and more particularly to an electronic panel having a pattern design of a light transmitting layer and an electronic device including the electronic panel.

### 2. Description of the Prior Art

Photosensitive elements (such as cameras) can be applied to the display panel to provide light sensing function. However, diffraction may occur due to the light shielding pattern in the display panel, thereby affecting the performance of the photosensitive element. Therefore, to reduce the influence of diffraction on the photosensitive element is still an important issue in the present field.

### SUMMARY OF THE DISCLOSURE

The present disclosure aims at providing an electronic panel and an electronic device.

In some embodiments, an electronic panel including a substrate, a first semiconductor element and a first color conversion element is provided by the present disclosure. The substrate has a functional region capable of allowing a light to pass through. The first semiconductor element is disposed on the functional region, wherein the first semiconductor element includes a first electrode, a first semiconductor layer disposed on the first electrode, and a second electrode disposed on the first semiconductor layer. The first color conversion element is disposed on the first semiconductor element and overlapped with the first semiconductor layer. In a top view of the electronic panel, a center of the first color conversion element is deviated from a center of the first semiconductor layer.

In some embodiments, an electronic device including the above-mentioned electronic panel and a sensing module disposed under the functional region is provided by the present disclosure.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 schematically illustrates a top view of an electronic panel according to a first embodiment of the present disclosure.

FIG. 2 schematically illustrates a cross-sectional view of the electronic panel according to the first embodiment of the present disclosure.

FIG. 3 schematically illustrates a cross-sectional view of a functional region of an electronic panel according to a second embodiment of the present disclosure.

FIG. 4 schematically illustrates a top view of the functional region of the electronic panel according to the second embodiment of the present disclosure.

FIG. 5 schematically illustrates a top view of a functional region of an electronic panel according to a third embodiment of the present disclosure.

FIG. 6 schematically illustrates a top view of a functional region of an electronic panel according to a fourth embodiment of the present disclosure.

FIG. 7 schematically illustrates a cross-sectional view of a functional region of an electronic panel according to a fifth embodiment of the present disclosure.

FIG. 8 schematically illustrates a cross-sectional view of a functional region of an electronic panel according to a sixth embodiment of the present disclosure.

FIG. 9 schematically illustrates a cross-sectional view of a functional region of an electronic panel according to a seventh embodiment of the present disclosure.

FIG. 10 schematically illustrates a cross-sectional view of a functional region of an electronic panel according to an eighth embodiment of the present disclosure.

FIG. 11 schematically illustrates a cross-sectional view of a functional region of an electronic panel according to a ninth embodiment of the present disclosure.

FIG. 12 schematically illustrates a cross-sectional view of a functional region of an electronic panel according to a tenth embodiment of the present disclosure.

FIG. 13 schematically illustrates a cross-sectional view of a functional region of an electronic panel according to an eleventh embodiment of the present disclosure.

FIG. 14 schematically illustrates a cross-sectional view of a functional region of an electronic panel according to a twelfth embodiment of the present disclosure.

FIG. 15 schematically illustrates a cross-sectional view of an electronic device according to an embodiment of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of the device, and certain elements in various drawings may not be drawn to scale. In addition, the number and dimension of each element shown in drawings are only illustrative and are not intended to limit the scope of the present disclosure.

Certain terms are used throughout the description and following claims to refer to particular elements. As one skilled in the art will understand, electronic equipment manufacturers may refer to an element by different names. This document does not intend to distinguish between elements that differ in name but not function.

In the following description and in the claims, the terms “include”, “comprise” and “have” are used in an open-ended fashion, and thus should be interpreted to mean “include, but not limited to . . . ”.

It will be understood that when an element or layer is referred to as being “disposed on” or “connected to” another element or layer, it can be directly on or directly connected to the other element or layer, or intervening elements or layers may be presented (indirectly). In contrast, when an element is referred to as being “directly on” or “directly connected to” another element or layer, there are no intervening elements or layers presented. When an element or a layer is referred to as being “electrically connected” to another element or layer, it can be a direct electrical connection or an indirect electrical connection. The electrical connection or coupling described in the present disclosure may refer to a direct connection or an indirect connection. In the case of a direct connection, the ends of the elements on two circuits are directly connected or connected to each other by a conductor segment. In the case of an indirect connection, switches, diodes, capacitors, inductors, resistors, other suitable elements or combinations of the above elements may be included between the ends of the elements on two circuits, but not limited thereto.

Although terms such as first, second, third, etc., may be used to describe diverse constituent elements, such constituent elements are not limited by the terms. The terms are used only to discriminate a constituent element from other constituent elements in the specification. The claims may not use the same terms, but instead may use the terms first, second, third, etc. with respect to the order in which an element is claimed. Accordingly, in the following description, a first constituent element may be a second constituent element in a claim.

According to the present disclosure, the thickness, length and width may be measured through optical microscope, and the thickness or width may be measured through the cross-sectional view in the electron microscope, but not limited thereto.

In addition, any two values or directions used for comparison may have certain errors. In addition, the terms “equal to”, “equal”, “the same”, “approximately” or “substantially” are generally interpreted as being within ±20%, ±10%, ±5%, ±3%, ±2%, ±1%, or ±0.5% of the given value.

In addition, the terms “the given range is from a first value to a second value” or “the given range is located between a first value and a second value” represents that the given range includes the first value, the second value and other values there between.

If a first direction is said to be perpendicular to a second direction, the included angle between the first direction and the second direction may be located between 80 to 100 degrees. If a first direction is said to be parallel to a second direction, the included angle between the first direction and the second direction may be located between 0 to 10 degrees.

Unless it is additionally defined, all terms (including technical and scientific terms) used herein have the same meaning as commonly understood by those ordinary skilled in the art. It can be understood that these terms that are defined in commonly used dictionaries should be interpreted as having meanings consistent with the relevant art and the background or content of the present disclosure, and should not be interpreted in an idealized or overly formal manner, unless it is specifically defined in the embodiments of the present disclosure.

It should be noted that the technical features in different embodiments described in the following can be replaced, recombined, or mixed with one another to constitute another embodiment without departing from the spirit of the present disclosure.

The electronic device of the present disclosure may include a display device, a sensing device, a back-light device, an antenna device, a tiled device or other suitable electronic devices, but not limited thereto. The electronic device may be a foldable electronic device, a flexible electronic device or a stretchable electronic device. The display device may for example be applied to laptops, common displays, tiled displays, vehicle displays, touch displays, televisions, monitors, smart phones, tablets, light source modules, lighting devices or electronic devices applied to the products mentioned above, but not limited thereto. The sensing device may for example include a biosensor, a touch sensor, a fingerprint sensor, an optical sensor, other suitable sensors or combinations of the above-mentioned sensors. The antenna device may for example include a liquid crystal antenna device or other suitable antenna devices. The tiled device may for example include a tiled display device or a tiled antenna device, but not limited thereto. The outline of the electronic device may be a rectangle, a circle, a polygon, a shape with curved edge or other suitable shapes. The electronic device may include electronic units, wherein the electronic units may include semiconductor units, and the semiconductor units include passive elements or active elements, such as capacitor, resistor, inductor, diode, transistor, sensors, integrated circuits, and the like. The diode may include a light emitting diode, a photo diode or a varicap diode. The light emitting diode may for example include an organic light emitting diode (OLED) or an in-organic light emitting diode. The in-organic light emitting diode may for example include a mini light emitting diode (mini LED), a micro light emitting diode (micro LED) or a quantum dot light emitting diode (QLED), but not limited thereto. The semiconductor unit may include a semiconductor layer or an electronic unit formed through a semiconductor process, but not limited thereto. It should be noted that the electronic device of the present disclosure may be combinations of the above-mentioned devices, but not limited thereto.

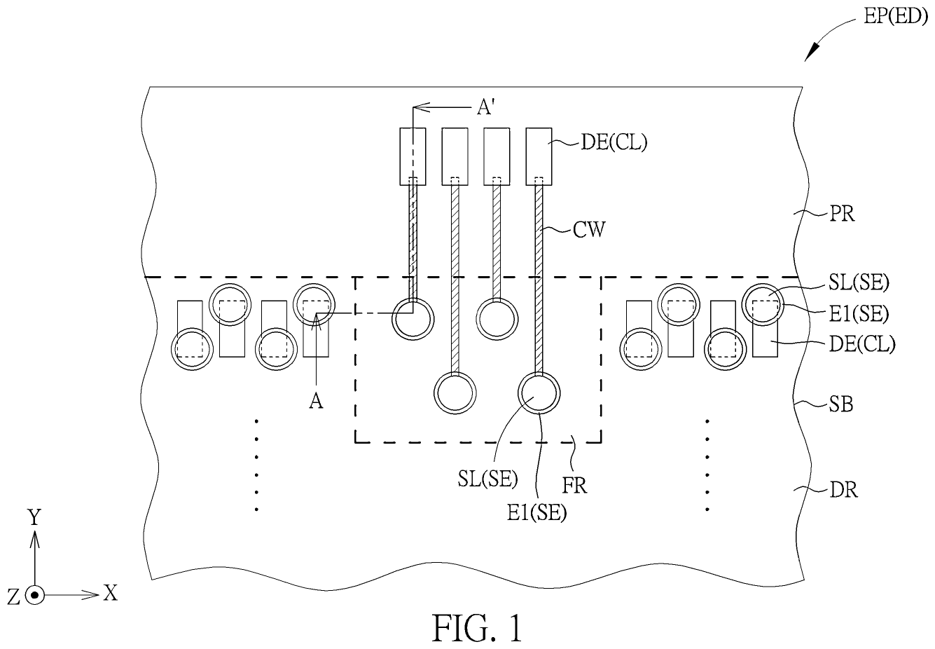

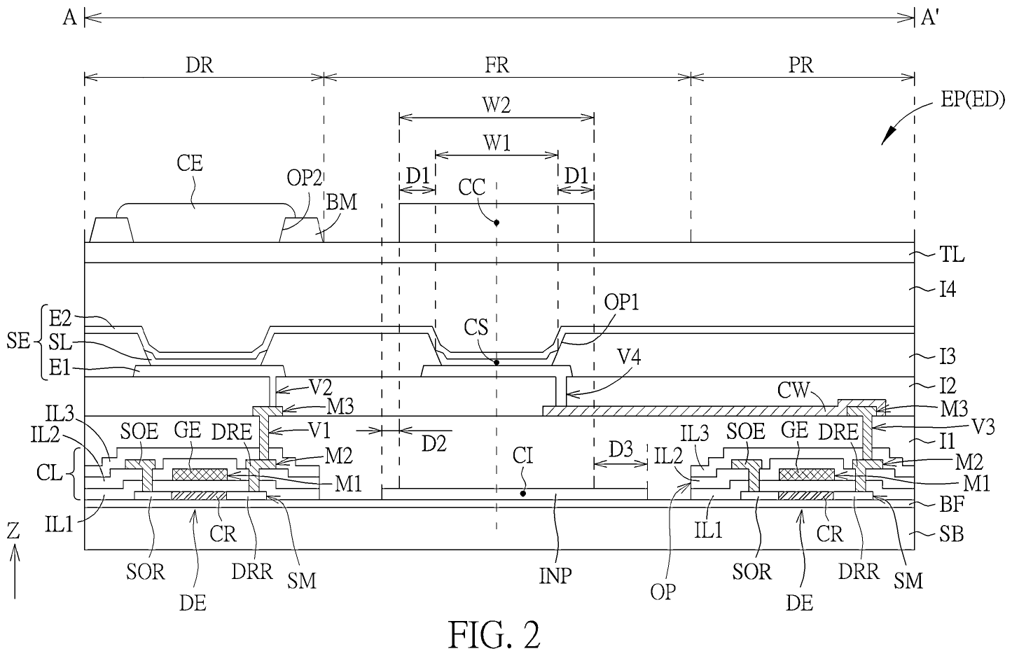

Referring to FIG. 1 and FIG. 2, FIG. 1 schematically illustrates a top view of an electronic panel according to a first embodiment of the present disclosure, and FIG. 2 schematically illustrates a cross-sectional view of the electronic panel according to the first embodiment of the present disclosure. Specifically, FIG. 2 shows the cross-sectional view of the structure shown in FIG. 1 along a section line A-A′. In order to simplify the figure, FIG. 1 just shows some of the layers and the elements of the electronic panel EP, and the structure of the electronic panel EP may refer to the structure shown in FIG. 2. According to the present disclosure, the electronic device ED may include an electronic panel EP and other elements that can be applied to the electronic panel EP. As shown in FIG. 2, the electronic panel EP includes a substrate SB, a circuit layer CL disposed on the substrate SB, semiconductor elements SE disposed on the circuit layer CL and color conversion elements CE disposed on the semiconductor elements SE, but not limited thereto. In the present embodiment, the electronic panel EP may for example include a display panel, but not limited thereto. In such condition, the semiconductor element SE may include any element that can exhibit semiconductor characteristics, such as a transistor, a photodiode or a light emitting diode, but not limited thereto. In addition, the color or wavelength of the light emitted by the semiconductor element SE may be filtered or converted into light of various colors through the color conversion element CE. The structures of the elements and the layers of the electronic panel EP will be detailed in the following.

The substrate SB may include a rigid substrate or a flexible substrate. The rigid substrate for example includes glass, quartz, sapphire, ceramic, other suitable materials or combinations of the above-mentioned materials. The flexible substrate for example includes polyimide (PI), polycarbonate (PC), polyethylene terephthalate (PET), other suitable materials or combinations of the above-mentioned materials.

As shown in FIG. 1, the substrate SB may include a display region DR, a functional region FR and a peripheral region PR. The display region DR may be the region in the electronic panel EP mainly used for displaying images. The light emitting elements (that is, the semiconductor elements SE) in the electronic panel EP may be disposed corresponding to the display region DR. “The semiconductor elements SE are disposed corresponding to the display region DR” mentioned above may represent that the semiconductor elements SE are overlapped with or at least partially overlapped with the display region DR in a top view direction (that is, parallel to the direction Z, which will not be redundantly describe in the following) of the electronic panel EP. Specifically, the semiconductor elements SE may be disposed on the display region DR of the substrate SB. The functional region FR may be defined as the region in the substrate SB corresponding to the photosensitive element. Specifically, the electronic panel EP and the photosensitive element(s) may be integrated into the electronic device ED, and the photosensitive element(s) may be disposed corresponding to the functional region FR of the substrate SB. The range of the functional region FR may for example be defined through the outer edge of the photosensitive element(s), but not limited thereto. The photosensitive element(s) may be disposed under the functional region FR of the substrate SB, or the photosensitive element(s) may be disposed at a side of the functional region FR of the substrate SB opposite to the semiconductor elements SE, but not limited thereto. The light may pass through the functional region FR, thereby being received by the photosensitive element(s). As shown in FIG. 1 and FIG. 2, one or more semiconductor elements SE may further be disposed corresponding to the functional region FR, that is, some of the semiconductor elements SE may be disposed on the functional region FR of the substrate SB. The semiconductor element(s) SE disposed corresponding to the functional region FR may emit light to provide display function. Specifically, the semiconductor element(s) SE corresponding to the functional region FR may be auxiliary light emitting element(s), and the semiconductor elements SE corresponding to the display region DR may be main light emitting elements. In such condition, the semiconductor element(s) SE corresponding to the functional region FR may form auxiliary pixel(s), and the semiconductor elements SE corresponding to the display region DR may form main pixels, but not limited thereto. In some embodiments, as shown in FIG. 1, the element density of the semiconductor element(s) SE corresponding to the functional region FR may be lower than the element density of the semiconductor elements SE corresponding to the display region DR, thereby improving the transmittance of the functional region FR. The peripheral region PR may be other region of the substrate SB except the display region DR and the functional region FR for disposing peripheral elements of the electronic panel EP.

The circuit layer CL may include various kinds of wires, circuits, electronic units (such as active elements and/or passive elements) that can be applied to the electronic panel EP, but not limited thereto. For example, For example, the circuit layer CL may include a driving unit DU, wherein the driving unit DU may be electrically connected to any suitable electronic unit in the electronic device ED. For example, the circuit layer CL may include driving elements DE, wherein the driving elements DE may be electrically connected to the semiconductor elements SE to drive the semiconductor elements SE. The driving elements DE may for example include thin film transistors (TFT), but not limited thereto. Specifically, the circuit layer CL may include a semiconductor layer SM, a conductive layer M1 and a conductive layer M2, but not limited thereto. The driving element DE may include the semiconductor layer SM, a gate electrode GE, a source electrode SOE and a drain electrode DRE. The semiconductor layer SM may include a channel region CR, a source region SOR and a drain region DRR. The conductive layer M1 may form the gate electrode GE of the driving element DE. In the top view direction of the electronic panel EP, the gate electrode GE may overlap the channel region CR of the semiconductor layer SM. The conductive layer M2 may form the source electrode SOE and the drain electrode DRE. The semiconductor layer SM may include semiconductor materials. The semiconductor materials for example include silicon or metal oxides such as low temperature polysilicon (LTPS) semiconductor, amorphous silicon (a-Si): semiconductor, organic semiconductors or metal oxide semiconductors, and the metal oxide semiconductors may for example include indium gallium zinc oxide (IGZO) semiconductor or indium gallium oxide (IGO) semiconductor, but not limited thereto. The circuit layer CL may include a plurality of driving elements DE, and these driving elements DE may include different semiconductor materials. For example, one of the driving elements DE may include low temperature polysilicon semiconductor, and another one of the driving elements DE may include metal oxide semiconductors. The conductive layer M1 and the conductive layer M2 may include any suitable conductive material such as metal materials, but not limited thereto. The circuit layer CL may further include an insulating layer IL1 located between the conductive layer M1 and the semiconductor layer SM, an insulating layer IL2 disposed on the conductive layer M1 and an insulating layer IL3 disposed on the conductive layer M2. The insulating layer IL1, the insulating layer IL2 and the insulating layer IL3 may include any suitable insulating material such as organic insulating materials or inorganic insulating materials. The insulating layer IL1 may for example be the gate insulating layer of the driving element DE. In the present embodiment, the electronic panel EP may optionally include a buffer layer BF disposed between the substrate SB and the circuit layer CL, but not limited thereto. The buffer layer BF may include any suitable insulating material. It should be noted that the structure of the circuit layer CL shown in FIG. 2 is exemplary, and the present embodiment is not limited thereto.

According to the present embodiment, the circuit layer CL may include two portions respectively corresponding to the display region DR and the peripheral region PR. That is, the circuit layer CL may not be disposed corresponding to the functional region FR. Specifically, as shown in FIG. 2, a portion of the circuit layer CL corresponding to the functional region FR (including the conductive layers, the insulating layers, and the like) may be removed to form an opening OP. The electronic panel EP of the present embodiment may further include an insulating layer I1 disposed on the circuit layer CL, wherein the portion of the insulating layer I1 corresponding to the functional region FR may be filled into the opening OP. In such condition, the semiconductor elements SE corresponding to the display region DR may be electrically connected to the driving elements DE in the circuit layer CL corresponding to the display region DR, and the semiconductor elements SE corresponding to the functional region FR may be electrically connected to the driving elements DE in the circuit layer CL corresponding to the peripheral region PR, but not limited thereto. Specifically, the electronic panel EP may further include an insulating layer I2 disposed between the insulating layer I1 and the semiconductor elements SE and a conductive layer M3 disposed between the insulating layer I1 and the insulating layer I2, wherein the conductive layer M3 may be disposed corresponding to the display region DR and the peripheral region PR. The insulating layer I1 and the insulating layer I2 may include any suitable insulating material such as organic insulating materials, but not limited thereto. The conductive layer M3 corresponding to the display region DR may be electrically connected to the driving element DE corresponding to the display region DR through a via 0 penetrating through the insulating layer I1 and the insulating layer IL3, and the semiconductor element SE (such as the first electrode E1 of the semiconductor element SE) corresponding to the display region DR may be electrically connected to the conductive layer M3 corresponding to the display region DR through a via V2 penetrating through the insulating layer I2. Therefore, the semiconductor elements SE corresponding to the display region DR may be electrically connected to the driving elements DE corresponding to the display region DR. In addition, the electronic panel EP may include a connecting wire CW disposed between the insulating layer I1 and the insulating layer I2, wherein the connecting wire CW may extend on the functional region FR and the peripheral region PR of the substrate SB. The connecting wire CW may be electrically connected to the conductive layer M3 corresponding to the peripheral region PR, thereby being electrically connected to the driving elements DE corresponding to the peripheral region PR through a via V3 penetrating through the insulating layer I1 and the insulating layer IL3. The semiconductor element SE (for example, the first electrode E1 of the semiconductor element SE) corresponding to the functional region FR may be electrically connected to the connecting wire CW through a via V4 penetrating through the insulating layer I2. Therefore, the semiconductor element SE corresponding to the functional region FR may be electrically connected to the driving element DE corresponding to the peripheral region PR. For example, as shown in FIG. 1, in the top view of the electronic panel EP, the semiconductor elements SE corresponding to the display region DR may respectively be electrically connected to one of the driving elements DE corresponding to the display region DR, and the semiconductor elements SE corresponding to the functional region FR may respectively be electrically connected to one of the driving elements DE corresponding to the peripheral region PR through one of the connecting wires CW extending from the functional region FR to the peripheral region PR, but not limited thereto. By making the circuit layer CL (or the driving element DE) not disposed corresponding to the functional region FR, the transmittance of the functional region FR may be improved. It should be noted that the above-mentioned electrical connection between the semiconductor element SE and the driving element DE is exemplary, and the present disclosure is not limited thereto.

As mentioned above, the semiconductor element SE of the present embodiment may include a light emitting element. The light emitting element for example includes a light emitting diode. The light emitting diode may include an in-organic light emitting diode or an organic light emitting diode (OLED). The in-organic light emitting diode may include a micro light emitting diode (micro LED), a mini light emitting diode (mini LED) or a quantum dot light emitting diode (QLED), but not limited thereto. For example, the semiconductor element SE of the present embodiment may be an organic light emitting diode that includes a first electrode E1, a semiconductor layer SL disposed on the first electrode E1 and a second electrode E2 disposed on the semiconductor layer SL. In other words, the semiconductor layer SL is disposed between the first electrode E1 and the second electrode E2. The semiconductor layer SL may include a light emitting layer. One of the first electrode E1 and the second electrode E2 may be a cathode, and another one of the first electrode E1 and the second electrode E2 may be an anode. The first electrode E1 and/or the second electrode E2 may include any suitable transparent conductive material such as indium tin oxide (ITO), but not limited thereto. The electronic panel EP may further include an insulating layer 13 disposed on the insulating layer I2. The insulating layer 13 may be disposed on the first electrodes E1 and has openings OP1. The openings OP1 may defined the disposition position of the semiconductor layers SL (or the light emitting layers) of the semiconductor elements SE. Specifically, the semiconductor layers SL may be disposed in the openings OP1 and thereby being electrically connected to the first electrodes E1 through the openings OP1. The second electrode E2 may be a continuous layer conformally formed along the surface of the insulating layer 13 and the surface of the semiconductor layers SL, but not limited thereto. The insulating layer 13 may serve as a pixel defining layer (PDL).

The electronic panel EP may further include an insulating layer 14, wherein the insulating layer 14 may be disposed between the semiconductor elements SE and the color conversion elements CE. The insulating layer 14 may serve as an encapsulation layer for encapsulating the semiconductor elements SE and the elements and the layers there below. The insulating layer 14 may include a multi-layer structure, such as a structure formed by stacking an inorganic layer, an organic layer and an inorganic layer in sequence, but not limited thereto.

The color conversion element CE may be disposed corresponding to the semiconductor element SE to convert the wavelength or the color of the light emitted by the semiconductor element SE to which the color conversion element CE corresponds. For example, a semiconductor element SE may correspond to a color conversion element CE, but not limited thereto. The color conversion element CE may include color filter, quantum dot, phosphor material, fluorescent material, other suitable light converting materials or combinations of the above-mentioned materials. For example, the color conversion element CE may include color filter in the present embodiment, but not limited thereto. The electronic panel EP may further include a black matrix layer BM, wherein the black matrix layer BM may be disposed to surround the color conversion element CE corresponding to the display region DR. In other words, the black matrix layer BM may be disposed corresponding to the display region DR. Specifically, the black matrix layer BM may be disposed on the display region DR and define a plurality of openings OP2, and the color conversion elements CE corresponding to the display region DR may be disposed in the openings OP2. In another aspect, the black matrix layer BM may not be disposed corresponding to the functional region FR, that is, the black matrix layer BM is not disposed on the functional region FR of the substrate SB, and the color conversion elements CE corresponding to the functional region FR may not be disposed in the opening OP2 of the black matrix layer BM. The above-mentioned design may improve the transmittance of the functional region FR. In such condition, the color conversion element CE corresponding to the functional region FR may protrude from the semiconductor layer SL of the semiconductor element SE to which the color conversion element CE corresponds. As shown in FIG. 2, in the cross-sectional view of the electronic panel EP, a side of a color conversion element CE may protrude from a side of the semiconductor layer SL of the semiconductor element SE corresponding to the color conversion element CE, and a distance D1 is included between the side of the color conversion element CE and the side of the semiconductor layer SL. According to the present embodiment, the distance D1 may range from 0.01 micrometers (μm) to 21.285 μm. Therefore, a width W2 of the color conversion element CE in a direction may be greater than a width W1 of the semiconductor layer SL of the semiconductor element SE to which the color conversion element CE corresponds in the direction, and the difference between the width W1 and the width W2 may range from 0.02 μm to 42.57 μm (that is, 0.02 μm≤W2−W1≤42.57 μm), but not limited thereto. Through the above-mentioned size design, the possibility that the large-angle light emitted from the semiconductor element SE does not pass through the color conversion element CE may be reduced, thereby improving the display quality of the electronic panel EP.

The electronic panel EP of the present embodiment may further include a touch layer TL, wherein the touch layer TL may be disposed between the insulating layer 14 and the color conversion elements CE, but not limited thereto. In some embodiments, the electronic panel EP may not include the touch layer TL. The touch layer TL may provide the touch function of the electronic panel EP, that is, the electronic panel EP may include the touch display panel. The touch layer TL may include one or more conductive layers and/or insulating layers. The touch layer TL is just shown as a single layer (for example, a conductive layer) in FIG. 2, but the structure thereof is not limited to what is shown in FIG. 2.

According to the present embodiment, the electronic panel EP may include an insulation pattern INP disposed between the functional region FR of the substrate SB and the semiconductor element SE corresponding to the functional region FR. The insulation pattern INP may include any suitable inorganic insulating material or organic insulating material. The insulation pattern INP may for example include a patterned island-shaped pattern, but not limited thereto. The insulation pattern INP may correspond to the semiconductor element SE disposed on the functional region FR. The insulation pattern INP has a center CI, the semiconductor layer SL of the semiconductor element SE has a center CS, wherein the center CI of the insulation pattern INP is deviated from the center CS of the semiconductor layer SL of the semiconductor element SE to which the insulation pattern INP corresponds. In other words, the center CI of the insulation pattern INP does not overlap the center CS of the semiconductor layer SL of the semiconductor element SE to which the insulation pattern INP corresponds in the top view direction of the electronic panel EP. In addition, in the cross-sectional view of the electronic panel EP, a side of an insulation pattern INP may protrude from a side of the color conversion element CE corresponding to the insulation pattern INP, and a distance D2 is included between the side of the insulation pattern INP and the side of the color conversion element CE; another side of the insulation pattern INP may protrude from another side of the color conversion element CE, and a distance D3 is included between the another side of the insulation pattern INP and the another side of the color conversion element CE, wherein the distance D2 is different from the distance D3. In other words, the protruding distances of the insulation pattern INP respectively at two sides of the color conversion element CE may be different. Through the disposition and pattern design of the insulation pattern INP, the irregularity of the layers corresponding to the functional region FR may increase, thereby reducing the influence of light diffraction in the functional region FR on the photosensitive element. In some embodiments, the insulation pattern INP may be disposed on any layer between the functional region FR and the semiconductor element SE corresponding to the functional region FR. In some embodiments, the insulation pattern INP may be formed of the buffer layer BF. Specifically, the buffer layer BF may be patterned to form the insulation pattern INP corresponding to the functional region FR. The refractive index of the insulating pattern INP may be different from the refractive index of the insulating layer 14 or the refractive index of the buffer layer BF, but not limited thereto. In addition, in the present embodiment, the color conversion element CE has a center CC, wherein the center CC of the color conversion element CE may overlap the center CS of the semiconductor layer SL of the semiconductor element SE to which the color conversion element CE corresponds in the top view direction of the electronic panel EP, but not limited thereto. In other words, the center CI of the insulation pattern INP may be deviated from the center CC of the color conversion element CE to which the insulation pattern INP corresponds. The feature that the electronic panel EP includes the insulation pattern INP mentioned in the present embodiment may be applied to the embodiments of the present disclosure. It should be noted that the “center” of the elements or the layers mentioned above may be the geometric center of the pattern of the elements or the layers in the top view, and the above-mentioned definition may be applied to the following embodiments, which will not be redundantly described.

In the present disclosure, the center of a layer may be defined in the shape of the projection (that is, the pattern in the top view direction or the top view) of the layer on a plane (for example, the plane XY) perpendicular to the top view direction of the electronic panel EP. In some embodiments, when the shape of the projection of the layer on a plane perpendicular to the top view direction of the electronic panel EP is a circle or an ellipse, the center of the layer may be the center of the shape of the projection. In some embodiments, when the shape of the projection of the layer on a plane perpendicular to the top view direction of the electronic panel EP is a rectangle, the center of the layer may be the intersection of the diagonal lines of the shape of the projection. In some embodiments, when the shape of the projection of the layer on a plane perpendicular to the top view direction of the electronic panel EP is a polygon or an irregular shape, the center of the layer may be the intersection of the diagonals of the minimum rectangle surrounding the shape of the projection. The definition of the centers of the layers in the present disclosure may refer to the method mentioned above, which will not be redundantly described in the following.

The electronic panel EP of the present embodiment may further include other suitable elements and/or layers, which is not limited to the structure shown in FIG. 1 and FIG. 2.

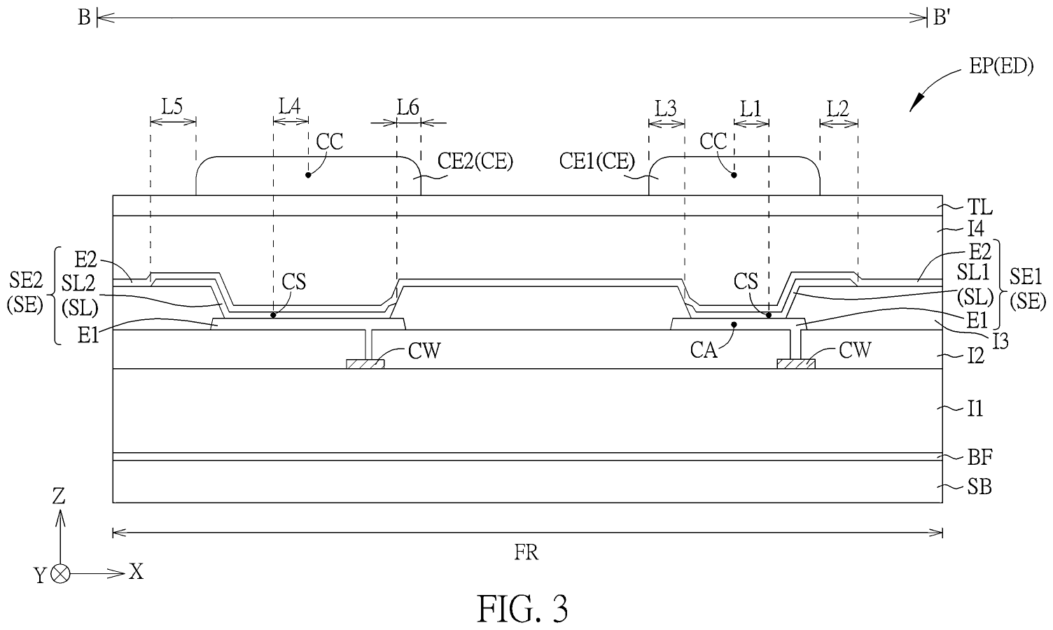

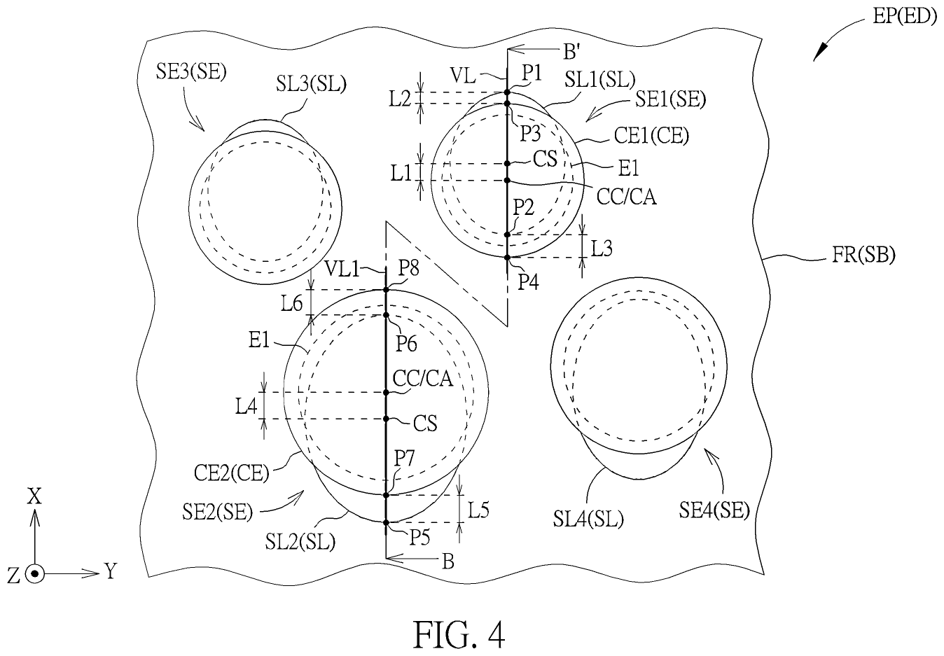

Referring to FIG. 3 and FIG. 4, FIG. 3 schematically illustrates a cross-sectional view of a functional region of an electronic panel according to a second embodiment of the present disclosure, and FIG. 4 schematically illustrates a top view of the functional region of the electronic panel according to the second embodiment of the present disclosure. Specifically, FIG. 3 shows the cross-sectional view of the structure shown in FIG. 4 along a section line B-B′. In order to simplify the figure, FIG. 4 just shows some of the elements or the layers of the electronic panel EP corresponding to the functional region FR of the substrate SB, and the structures of the other elements or layers may refer to FIG. 2, which will not be redundantly described. In the present embodiment, the four semiconductor elements SE disposed on the functional region FR shown in FIG. 4 may for example form a pixel (that is, the auxiliary pixel mentioned above), but not limited thereto. Specifically, each of the semiconductor elements SE corresponding to the functional region DR may form an auxiliary sub-pixel with its corresponding color conversion element CE respectively, and four auxiliary sub-pixels may form one auxiliary pixel. In the present embodiment, a pixel may for example be formed of two green sub-pixels, a red sub-pixel and a blue sub-pixel, and these sub-pixels may be mixed into a white light, but not limited thereto. In other words, FIG. 4 for example shows the top view of a pixel disposed on the functional region FR, but not limited thereto. In some embodiments, the four semiconductor elements SE shown in FIG. 4 may be included in different sub-pixels. The composition of the main pixels disposed corresponding to the display region DR may refer to the composition of the above-mentioned auxiliary pixels, and will not be redundantly described.

As shown in FIG. 3, the electronic panel EP includes a first semiconductor element SE1 disposed on the functional region FR of the substrate SB and a first color conversion element CE1 disposed on the first semiconductor element SE1. The first semiconductor element SE1 includes a first electrode E1, a first semiconductor layer SL1 disposed on the first electrode E1 and a second electrode E2 disposed on the first semiconductor layer SL1. The color conversion element CE1 may overlap the first semiconductor layer SL1 of the first semiconductor element SE1 in the top view direction of the electronic panel EP to convert the wavelength or the color of the light emitted by the first semiconductor element SE1. According to the present embodiment, as shown in FIG. 4, in the top view direction of the electronic panel EP, the first semiconductor layer SL1 of the first semiconductor element SE1 has a center CS, and the first color conversion element CE1 has a center CC, wherein the center CC of the first color conversion element CE1 is deviated from the center CS of the first semiconductor layer SL1. In the present embodiment, the position of the center CS may be changed by making the first semiconductor layer SL1 extend, such that the center CS may be deviated from the center CC of the first color conversion element CE1. In the present disclosure, “the extension of the first semiconductor layer SL1” mentioned above may indicate any pattern change of the first semiconductor layer SL1 that changes the center CS of the first semiconductor layer SL1. Specifically, compared with the structure in which the center CS of the semiconductor layer SL overlaps the center CC of the color conversion element CE shown in FIG. 2, the first semiconductor layer SL1 of the present embodiment may extend toward a direction, such that the center of the first semiconductor layer SL1 may move (for example, move toward the direction) to be deviated from the center CC of the first color conversion element CE1. The definition of “extension of layers” mentioned in the following may refer to the contents above, and will not be redundantly described.

According to the present embodiment, in the top view direction of the electronic panel EP, the first semiconductor layer SL1 may for example extend and be protruded from the first color conversion element CE1, but not limited thereto. For example, as shown in FIG. 4, the first semiconductor layer SL1 may extend toward the direction X, such that the center CS may move toward the direction X. In such condition, the center CS of the first semiconductor layer SL1 may be deviated from the center CC of the first color conversion element CE1 in the direction X, or the center CC of the first color conversion element CE1 may be deviated from the center CS of the first semiconductor layer SL1 in the direction −X. In some embodiments, the first semiconductor layer SL1 may extend toward two directions which are opposite to each other (for example, the direction X and the direction −X, but not limited thereto), and the degrees of extension of the first semiconductor layer SL1 in the two directions may be different, such that the position of the center CS is changed. In such condition, the size or shape of the first color conversion element CE1 may be the same as the size or shape of the first electrode E1, thereby reducing the possibility of affecting the display effect of the electronic panel EP due to deformation of the first semiconductor layer SL1. It should be noted that the first semiconductor layer SL1 may extend toward any direction to change the position of the center CS. In the present embodiment, the center CC of the first color conversion element CE1 may be deviated from the center CS of the first semiconductor layer SL1 by a first distance L1. The first distance L1 may be the distance between the center CC of the first color conversion element CE1 and the center CS of the first semiconductor layer SL1 in the top view direction of the electronic panel EP. According to the present embodiment, the first distance L1 may range from 0.1 micrometers (μm) to 10 μm (that is, 0.1 μm≤L1≤10 μm). In some embodiments, the first distance L1 may range from 0.3 μm to 9 μm (that is, 0.3 μm≤L1≤9 μm). In some embodiments, the first distance L1 may range from 0.5 μm to 8 μm (that is, 0.5 μm≤L1≤8 μm). By making the pattern of the first semiconductor layer SL1 extend toward a direction, such that the center CS of the first semiconductor layer SL1 is deviated from the center CC of the first color conversion element CE1, the arrangement irregularity of the layers or the elements (such as the first semiconductor layer SL1) corresponding to the functional region FR may increase, thereby reducing the possibility of diffraction of light in the functional region FR and affecting the photosensitive element. When the first distance L1 is less than 0.1 μm, the irregularity of the pattern of the first semiconductor layer SL1 may not be obvious enough to effectively reduce the occurrence of diffraction. When the first distance L1 is greater than 10 μm, the overlapping portion of the first semiconductor layer SL1 and the first color conversion element CE1 may be too small, thereby affecting the display effect of the electronic panel EP. In addition, in the present embodiment, the first electrode E1 may have a center CA, wherein the center CC of the first color conversion element CE1 may overlap the center CA of the first electrode E1 in the top view direction of the electronic panel EP, but not limited thereto.

As shown in FIG. 4, in the top view direction of the electronic panel EP, a virtual line VL may be defined by the center CS of the first semiconductor layer SL1 and the center CC of the first color conversion element CE1. The virtual line VL may be a straight line passing through the center CS and the center CC. The extending direction of the virtual line VL may be substantially parallel to the extending direction of the first semiconductor layer SL1 (or the direction in which the center CS is deviated from the center CC), that is, the direction X. According to the present embodiment, the virtual line VL may cross an edge of the first semiconductor layer SL1 at a first point P1 and a second point P2, and the virtual line VL may cross an edge of the first color conversion element CE1 at a third point P3 and a fourth point P4, wherein the third point P3 is located between the first point P1 and the center CC of the first color conversion element CE1, and the second point P2 is located between the fourth point P4 and the center CC of the first color conversion element CE1. That is, the first point P1 may protrude from the first color conversion element CE1, and the second point P2 may not protrude from the first color conversion element CE1. In other words, a side of the first semiconductor layer SL1 (for example, the side corresponding to the first point P1) may extend, such that the edge of the side may protrude from the edge of the first color conversion element CE1; and the edge of another side of the first semiconductor layer SL1 (for example, the side corresponding to the second point P2) may not protrude from the edge of the first color conversion element CE1, as shown in FIG. 2. In the present embodiment, as shown in FIG. 3 and FIG. 4, a second distance L2 may be included between the first point P1 and the third point P3, and a third distance L3 may be included between the second point P2 and the fourth point P4, wherein the second distance L2 may be different from the third distance L3. That is, the protruding distance (that is, the second distance L2) of the first semiconductor layer SL1 protruding from the first color conversion element CE1 at a side of the first color conversion element CE1 may be different from the third distance L3 between the first semiconductor layer SL1 and the first color conversion element CE1 at another side of the first color conversion element CE1 opposite to the side. In the present embodiment, the second distance L2 and the third distance L3 may range from 0.1 μm to 20 μm (that is, 0.1 μm≤L2, L3≤20 μm), but not limited thereto. In some embodiments, the second distance L2 and the third distance L3 may range from 0.3 μm to 18 μm (that is, 0.3 μm≤L2, L3≤18 μm). In some embodiments, the second distance L2 and the third distance L3 may range from 0.5 μm to 16 μm (that is, 0.5 μm≤L2, L3≤16 μm). By making the second distance L2 and the third distance L3 different from each other, the arrangement irregularity of the layers or the elements corresponding to the functional region FR may increase.

As mentioned above, although it is not shown in FIG. 3, the electronic panel EP of the present embodiment may include the insulation pattern INP shown in FIG. 2, wherein the insulation pattern INP may be disposed between the functional region FR of the substrate SB and the first semiconductor element SE1, and the center CI of the insulation pattern INP may be deviated from the center CS of the first semiconductor layer SL1.

As shown in FIG. 3 and FIG. 4, the electronic panel EP may further include a second semiconductor element SE2 disposed on the functional region FR of the substrate SB and a second color conversion element CE2 disposed on the second semiconductor element SE2. The second semiconductor element SE2 may include a first electrode E1, a second semiconductor layer SL2 disposed on the first electrode E1, and a second electrode E2 disposed on the second semiconductor layer SL2. The second semiconductor element SE2 may be located in the same auxiliary pixel as the first semiconductor element SE1, but not limited thereto. In the present embodiment, the second semiconductor layer SL2 may extend toward a direction, such that the center CS of the second semiconductor layer SL2 may be deviated from the center CC of the second color conversion element CE2, wherein the extending direction of the second semiconductor layer SL2 may be different from the extending direction of the first semiconductor layer SL1. For example, as shown in FIG. 3 and FIG. 4, the first semiconductor layer SL1 may extend in the direction X, and the second semiconductor layer SL2 may extend in the direction −X, but not limited thereto. In some embodiments, the first semiconductor layer SL1 may extend in a direction, and the second semiconductor layer SL2 may extend in another direction different from the direction, wherein the direction and the another direction may be any direction and are not limited to the direction X and the direction Y. Therefore, the center CC of the first color conversion element CE1 may be deviated from the center CS of the first semiconductor layer SL1 in a first direction, and the center CC of the second color conversion element CE2 may be deviated from the center CS of the second semiconductor layer SL2 in a second direction, wherein the first direction may be different from the second direction. The first direction mentioned above may be the direction form the center CS of the first semiconductor layer SL1 to the center CC of the first color conversion element CE1, and the second direction may be the direction from the center CS of the second semiconductor layer SL2 to the center CC of the second color conversion element CE2. For example, the first direction may be the direction −X, and the second direction may be the direction X, but not limited thereto.

In addition, in the present embodiment, the center CC of the first color conversion element CE1 may be deviated from the center CS of the first semiconductor layer SL1 by a first distance L1, and the center CC of the second color conversion element CE2 may be deviated from the center CS of the second semiconductor layer SL2 by a fourth distance L4, wherein the first distance L1 may be different from the fourth distance L4. The range of the fourth distance L4 may refer to the range of the first distance L1 mentioned above. In other words, the extending degree of the first semiconductor layer SL1 may be different from the extending degree of the second semiconductor layer SL2. Therefore, the protruding distance of the second semiconductor layer SL2 protruding from the second color conversion element CE2 may be different from the protruding distance (for example, the second distance L2) of the first semiconductor layer SL1 protruding from the first color conversion element CE1. Specifically, a virtual line VL1 may be defined by the center CC of the second color conversion element CE2 and the center CS of the second semiconductor layer SL2, the virtual line VL1 may cross an edge of the second semiconductor layer SL2 at a fifth point P5 and a sixth point P6 and cross an edge of the second color conversion element CE2 at a seventh point P7 and an eighth point P8, wherein the seventh point P7 is located between the fifth point P5 and the center CC of the second color conversion element CE2, and the sixth point P6 is located between the eighth point P8 and the center CC of the second color conversion element CE2. A fifth distance L5 may be located between the fifth point P5 and the seventh point P7, and the fifth distance L5 may be the protruding distance of the second semiconductor layer SL2 protruding from the second color conversion element CE2, wherein the second distance L2 may be different from the fifth distance L5, but not limited thereto. Similar to the structure of the first semiconductor element SE1, a sixth distance L6 may be included between the sixth point P6 and the eighth point P8, wherein the sixth distance L6 may be different from the fifth distance L5.

By making the semiconductor layers SL of the semiconductor elements SE corresponding to the functional region FR extending toward different directions or through the above-mentioned distance design, the arrangement irregularity of the layers or the elements corresponding to the functional region FR may increase, thereby reducing the possibility of diffraction of light in the functional region FR and affecting the photosensitive element. For example, as shown in FIG. 4, the electronic panel EP may further include a third semiconductor element SE3 and a fourth semiconductor element SE4 corresponding to the functional region FR, and the third semiconductor element SE3 and the fourth semiconductor element SE4 respectively include a third semiconductor layer SL3 and a fourth semiconductor layer SL4. In some embodiments, as shown in FIG. 4, the third semiconductor layer SL3 may extend toward the direction X, and the fourth semiconductor layer SL4 may extend toward the direction −X. In some embodiments, the first semiconductor layer SL1 may extend toward the direction −X, the second semiconductor layer SL2 may extend toward the direction X, the third semiconductor layer SL3 may extend toward the direction −Y, and the fourth semiconductor layer SL4 may extend toward the direction Y.

It should be noted that although it is not shown in FIG. 3, The connecting wire CW connected to the first semiconductor element SE1 and the second semiconductor element SE2 may be electrically connected to the driving elements DE corresponding to the peripheral region PR. The structures of other elements and layers shown in FIG. 3 and the portion of the electronic panel EP corresponding to the display region DR and the peripheral region PR of the substrate SB may refer to FIG. 2 and related contents mentioned above, which will not be redundantly described.

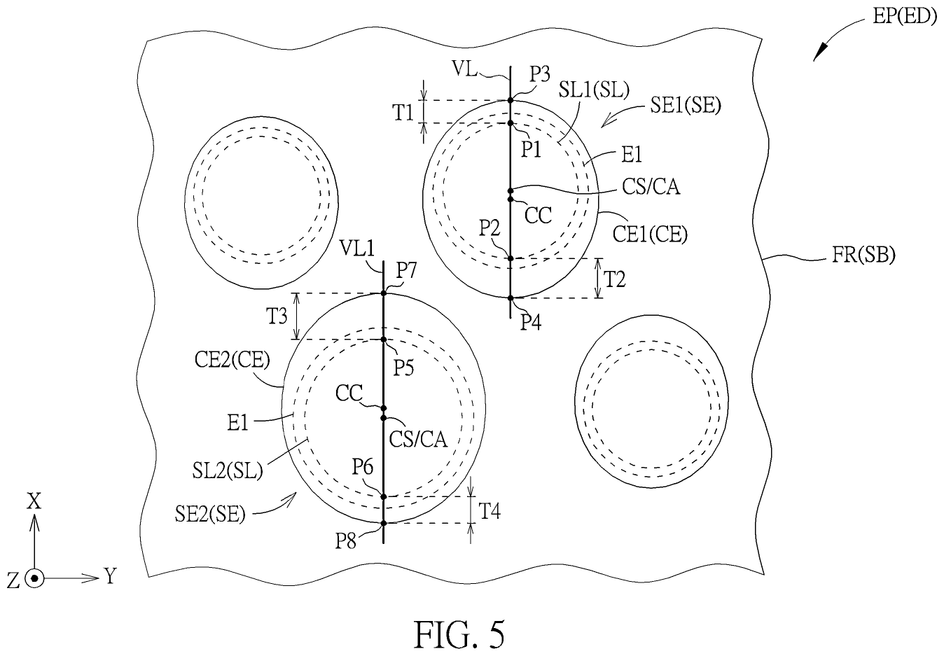

Referring to FIG. 5, FIG. 5 schematically illustrates a top view of a functional region of an electronic panel according to a third embodiment of the present disclosure. In order to simplify the figure, FIG. 5 just shows some of the elements or the layers of the electronic panel EP corresponding to the functional region FR of the substrate SB, and the structures of the other elements or layers may refer to FIG. 2, which will not be redundantly described. According to the present embodiment, the color conversion element CE corresponding to the functional region FR (or corresponding to the semiconductor element SE on the functional region FR) may extend toward a direction (for example, compared with the color conversion element CE shown in FIG. 2, the color conversion element CE of the present embodiment may extend toward a direction), such that the center CC of the color conversion element CE may be deviated from the center CS of the semiconductor layer SL of the semiconductor element SE to which the color conversion element CE corresponds. For example, as shown in FIG. 5, the first color conversion element CE1 corresponding to the first semiconductor element SE1 may extend toward the direction −X, such that the center CC of the first color conversion element CE1 is deviated from the center CS of the first semiconductor layer SL1 in the direction −X, but not limited thereto. The range of the distance in which the center CC of the first color conversion element CE1 is deviated from the center CS of the first semiconductor layer SL1 may refer to the range of the first distance L1 mentioned above, but not limited thereto. In such condition, in the top view direction of the electronic panel EP, the virtual line VL may be defined by the center CS of the first semiconductor layer SL1 and the center CC of the first color conversion element CE1, the virtual line VL may cross the edge of the first semiconductor layer SL1 at the first point P1 and the second point P2, and the virtual line VL may cross the edge of the first color conversion element CE1 at the third point P3 and the fourth point P4, wherein the first point P1 is located between the third point P3 and the center CC of the first color conversion element CE1, and the second point P2 is located between the fourth point P4 and the center CC of the first color conversion element CE1. In other words, the first color conversion element CE1 may cover the first semiconductor layer SL1 in the top view direction of the electronic panel EP. A first distance T1 may be included between the first point P1 and the third point P3, and a second distance T2 may be included between the second point P2 and the fourth point P4, wherein the first distance T1 and the second distance T2 may be different. For example, the first distance T1 may be less than the second distance T2, but not limited thereto. By making the first color conversion element CE1 extend toward a direction, such that the center CC of the first color conversion element CE1 is deviated from the center CS of the first semiconductor layer SL1, the arrangement irregularity of the layers or the elements corresponding to the functional region FR may increase, thereby reducing the possibility of diffraction of light in the functional region FR and affecting the photosensitive element. It should be noted that in addition to the first color conversion element CE1 mentioned above, other color conversion elements CE corresponding to the functional region FR may respectively extend toward a direction, and these color conversion elements CE may randomly extend toward any direction. In some embodiments, the first color conversion element CE1 may extend toward two directions which are opposite to each other (for example, the direction X and the direction −X, but not limited thereto), and the degrees of extension of the first color conversion element CE1 in the two directions may be different, such that the first distance T1 may be different from the second distance T2, thereby changing the position of the center CC. In addition, in the present embodiment, the center CA of the first electrode E1 may overlap the center CS of the first semiconductor layer SL1, but not limited thereto.

As shown in FIG. 5, the electronic panel EP may further include a second semiconductor element SE2 corresponding to the functional region FR and a second color conversion element CE2 corresponding to the second semiconductor element SE2, wherein the second color conversion element CE2 may extend toward a direction (for example, the direction X), such that the center CC of the second color conversion element CE2 is deviated from the center CS of the second semiconductor layer SL2. In such condition, in the top view direction of the electronic panel EP, the virtual line VL1 may be defined by the center CS of the second semiconductor layer SL2 and the center CC of the second color conversion element CE2, the virtual line VL1 may cross the edge of the second semiconductor layer SL2 at the fifth point P5 and the sixth point P6, and the virtual line VL1 may cross the edge of the second color conversion element CE2 at the seventh point P7 and the eighth point P8. Similarly, the third distance T3 between the fifth point P5 and the seventh point P7 may be different from the fourth distance T4 between the sixth point P6 and the eighth point P8. In addition, in the present embodiment, the degrees of extension of the color conversion elements CE corresponding to the functional region FR may be different. Specifically, as shown in FIG. 5, the extension degree of the first color conversion element CE1 may be represented by the second distance T2 between the second point P2 and the fourth point P4, and the extension degree of the second color conversion element CE2 may be represented by the third distance T3 between the fifth point P5 and the seventh point P7, wherein the second distance T2 may be different from the third distance T3. Therefore, the arrangement irregularity of the layers or the elements corresponding to the functional region FR may increase.

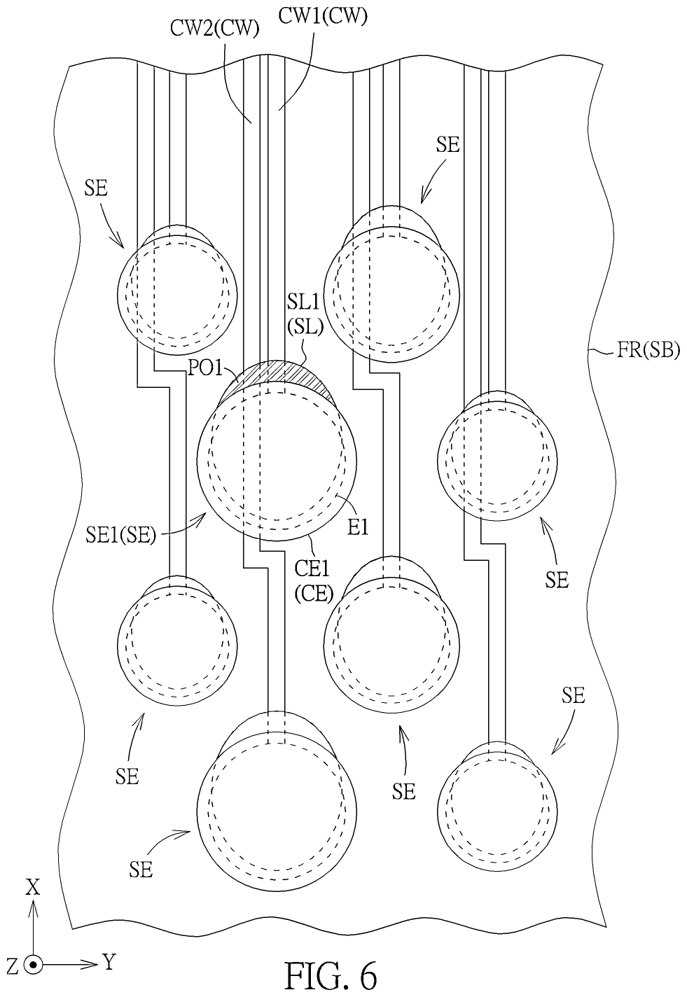

Referring to FIG. 6, FIG. 6 schematically illustrates a top view of a functional region of an electronic panel according to a fourth embodiment of the present disclosure. In order to simplify the figure, FIG. 6 just shows some of the elements or the layers of the electronic panel EP corresponding to the functional region FR of the substrate SB, and the structures of the other elements or layers may refer to FIG. 2, which will not be redundantly described. In the present embodiment, the semiconductor layer SL of the semiconductor element SE corresponding to the functional region FR may extend toward a direction (that is, compared with the semiconductor element SE shown in FIG. 2, the semiconductor layer SL of the semiconductor element SE of the present embodiment may extend toward a direction), such that the center of the semiconductor layer SL may be deviated from the center of the color conversion element CE to which the semiconductor layer SL corresponds. For example, as shown in FIG. 6, the first semiconductor layer SL1 of the first semiconductor element SE1 disposed on the functional region FR may extend toward the direction X, but not limited thereto. It should be noted that although FIG. 6 shows the structure that the semiconductor layers SL of the semiconductor elements SE extend toward the same direction, the present embodiment is not limited thereto. In the present embodiment, since the semiconductor layer SL of the semiconductor element SE may extend toward a direction, the semiconductor layer SL may include a portion protruding from the color conversion element CE corresponding to the semiconductor element SE. For example, the first semiconductor layer SL1 may include a portion PO1 protruding from the first color conversion element CE1, but not limited thereto. According to the present embodiment, the portion of f a semiconductor layer SL of a semiconductor element SE protruding from the color conversion element CE corresponding to the semiconductor element SE may overlap or at least partially overlap the connecting wire CW electrically connected to the semiconductor element SE (for example, the first electrode E1 of the semiconductor element SE) in the top view direction of the electronic panel EP. Specifically, as shown in FIG. 6, the connecting wire CW1 electrically connected to the first semiconductor element SE1 may overlap the portion PO1 of the first semiconductor layer SL1 in the top view direction of the electronic panel EP, or in other words, in the top view of the electronic panel EP, the connecting wire CW1 electrically connected to the first semiconductor element SE1 may pass through the portion PO1 of the first semiconductor layer SL1. By making the connecting wire CW overlapped with the portion of the semiconductor layer SL protruding from the color conversion element CE, the influence of the connecting wire CW on the transmittance of the functional region FR may be reduced. In some embodiments, the portion of a semiconductor layer SL of a semiconductor element SE protruding from the color conversion element CE corresponding to the semiconductor element SE may overlap or at least partially overlap the connecting wires CW electrically connected to other semiconductor elements SE in the top view direction of the electronic panel EP. For example, as shown in FIG. 6, the portion PO1 of the first semiconductor layer SL1 may further overlap the connecting wire CW2 electrically connected to the second semiconductor element SE2.

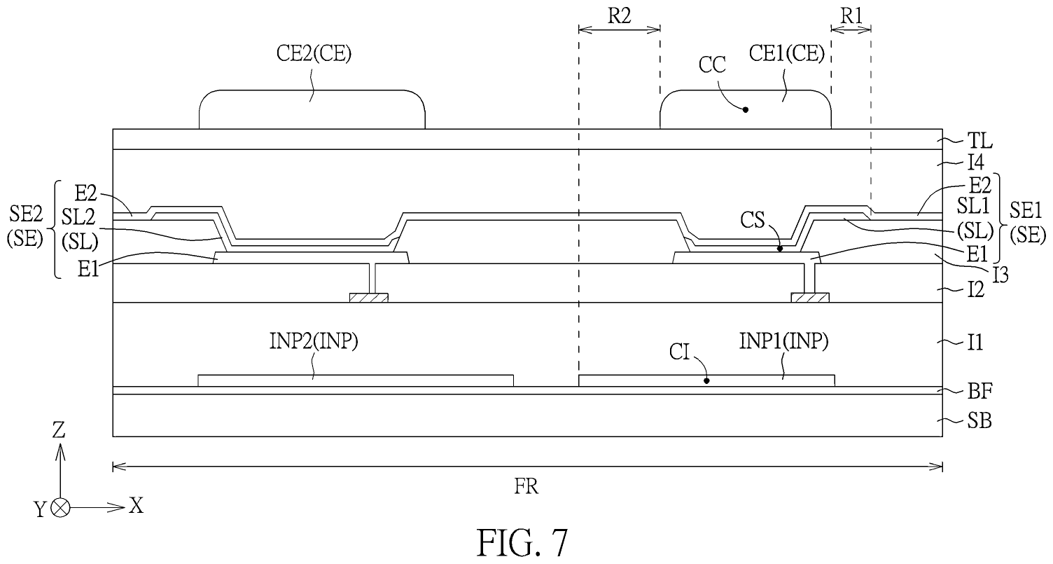

Referring to FIG. 7, FIG. 7 schematically illustrates a cross-sectional view of a functional region of an electronic panel according to a fifth embodiment of the present disclosure. In order to simplify the figure, FIG. 7 just shows some of the elements or the layers of the electronic panel EP corresponding to the functional region FR of the substrate SB, and the structures of the other elements or layers may refer to FIG. 2, which will not be redundantly described. The electronic panel EP of the present embodiment may include the first semiconductor element SE1 disposed on the functional region FR, the first color conversion element CE1 disposed on the first semiconductor element SE1, and an insulation pattern INP1 disposed between the functional region FR and the first semiconductor element SE1. The insulation pattern INP1 may be disposed on the buffer layer BF and may correspond to the first semiconductor element SE1, but not limited thereto. According to the present embodiment, the first semiconductor layer SL1 of the first semiconductor element SE1 may extend toward a direction (that is, compared with the semiconductor layer SL shown in FIG. 2, the first semiconductor layer SL1 of the first semiconductor element SE1 of the present embodiment may extend toward a direction), and the insulation pattern INP1 corresponding to the first semiconductor element SE1 may extend toward another direction, wherein the extending direction of the first semiconductor layer SL1 may be different from the extending direction of the insulation pattern INP1, but not limited thereto. For example, as shown in FIG. 7, the first semiconductor layer SL1 may extend toward the direction X, and the insulation pattern INP1 may extend toward the direction −X, but not limited thereto. In such condition, the center CS of the first semiconductor layer SL1 and the center CI of the insulation pattern INP1 may be deviated from the center CC of the first color conversion element CE1, wherein the center CS and the center CI may be located at two sides of the center CC respectively, but not limited thereto. In addition, the center CS of the first semiconductor layer SL1 may be deviated from the center CI of the insulation pattern INP1. Similarly, the second semiconductor layer SL2 of the second semiconductor element SE2 may extend toward the direction −X, and the insulation pattern INP2 corresponding to the second semiconductor element SE2 may extend toward the direction X. It should be noted that although FIG. 7 shows the structure that the first semiconductor layer SL1 and the insulation pattern INP1 respectively extend toward the directions that are opposite to each other, the present embodiment is not limited thereto. In some embodiments, the extending direction of the first semiconductor layer SL1 may be opposite to the extending direction of the insulation pattern INP1. In some embodiments, the extending direction of the first semiconductor layer SL1 and the extending direction of the insulation pattern INP1 may be any two different directions. In addition, according to the present embodiment, as shown in FIG. 7, a side of the first semiconductor layer SL1 may extend toward the direction X and protrude from the first color conversion element CE1, and a first distance R1 may be included between the side of the first semiconductor layer SL1 and the first color conversion element CE1; a side of the insulation pattern INP1 may extend toward the direction −X and protrude from the first color conversion element CE1, and a second distance R2 may be included between the side of the insulation pattern INP1 and the first color conversion element CE1, wherein the first distance R1 may be different from the second distance R2. Through the pattern design or distance design of the semiconductor layer SL and the insulation pattern INP mentioned above, the arrangement irregularity of the layers or the elements corresponding to the functional region FR may increase, thereby reducing the possibility of diffraction of light in the functional region FR and affecting the photosensitive element.

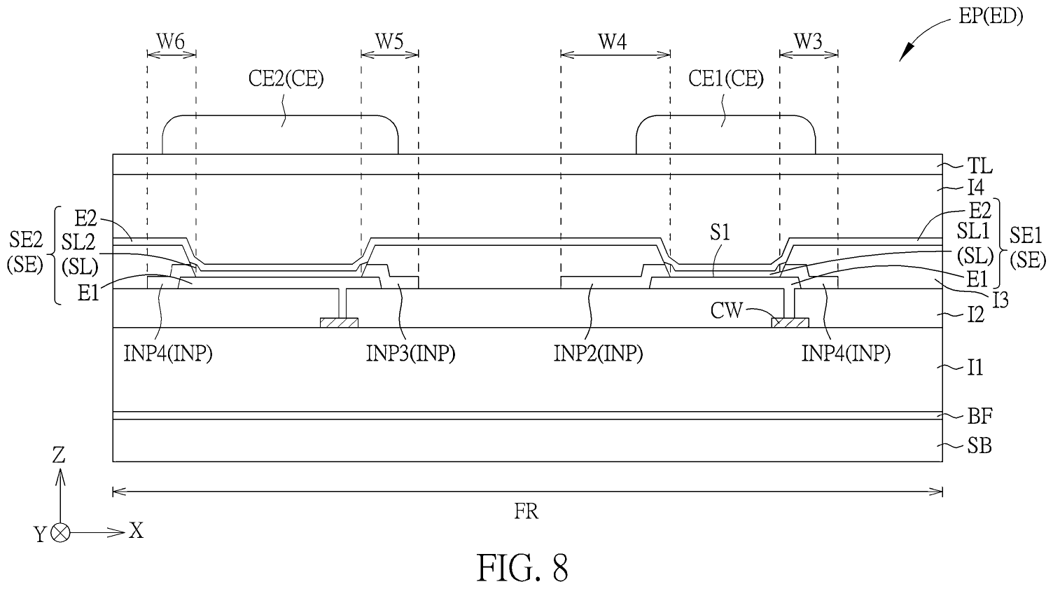

Referring to FIG. 8, FIG. 8 schematically illustrates a cross-sectional view of a functional region of an electronic panel according to a sixth embodiment of the present disclosure. In order to simplify the figure, FIG. 8 just shows some of the elements or the layers of the electronic panel EP corresponding to the functional region FR of the substrate SB, and the structures of the other elements or layers may refer to FIG. 2, which will not be redundantly described. According to the present embodiment, the electronic panel EP may include the insulation pattern INP disposed on the insulating layer I2, wherein the insulation pattern INP may be disposed adjacent to the first electrode E1 of the first semiconductor element SE1 (and/or the second semiconductor element SE2). For example, as shown in FIG. 8, the insulation pattern INP1 and the insulation pattern INP2 may be disposed adjacent to both sides of the first electrode E1, but not limited thereto. In some embodiments, the insulation pattern INP may extend along the side surface of the first electrode E1 upward to the top surface S1 of the first electrode E1, but not limited thereto. Therefore, a portion of the insulation pattern INP may be disposed on the first electrode E1 and cover the first electrode E1. In such condition, the insulation pattern INP may be disposed adjacent to the first semiconductor layer SL1. The insulating layer 13 may cover the insulation pattern INP. According to the present embodiment, in the cross-sectional view of the electronic panel EP, the insulation patterns INP (for example, the insulation pattern INP1 and the insulation pattern INP2) located at two sides of the first electrode E1 may have different widths. As shown in FIG. 8, the insulation pattern INP1 disposed at a side of the first electrode E1 of the first semiconductor element SE1 may have a width W3, and the insulation pattern INP2 disposed at the other side of the first electrode E1 of the first semiconductor element SE1 may have a width W4, wherein the width W3 may be different from the width W4, but not limited thereto. “The width W3 of the insulation pattern INP1” mentioned above may be defined as the width of the projection of the insulation pattern INP1 on a plane perpendicular to the top view direction of the electronic panel EP, but not limited thereto. The width W4 of the insulation pattern INP2 may be defined in the same way, and will not be redundantly described. Similarly, the width W5 of the insulation pattern INP3 disposed at a side of the first electrode E1 of the second semiconductor element SE2 may be different from the width W6 of the insulation pattern INP4 disposed at the other side of the first electrode E1 of the second semiconductor element SE2. In addition, the width W3, the width W4, the width W5 and the width W6 may be different from each other, but not limited thereto. Through the disposition and/or the size design of the insulation patterns INP, the arrangement irregularity of the layers or the elements corresponding to the functional region FR may increase, thereby reducing the possibility of diffraction of light in the functional region FR and affecting the photosensitive element.

It should be noted that the structure of the insulation pattern INP of the present embodiment is not limited to what is shown in FIG. 8. In some embodiments, the insulation pattern INP may not be disposed on the first electrode E1. For example, the insulation pattern INP may be disposed adjacent to the first electrode E1 but not extend along the side surface of the first electrode E1. In some embodiments, in the cross-sectional view of the electronic panel EP, the insulation pattern INP may only be disposed at a side of the first electrode E1. For example, the electronic panel EP may include the insulation pattern INP1 or the insulation pattern INP2 disposed at a side of the first electrode E1 of the first semiconductor element SE1 and/or include the insulation pattern INP3 or the insulation pattern INP4 disposed at a side of the first electrode E1 of the second semiconductor element SE2.

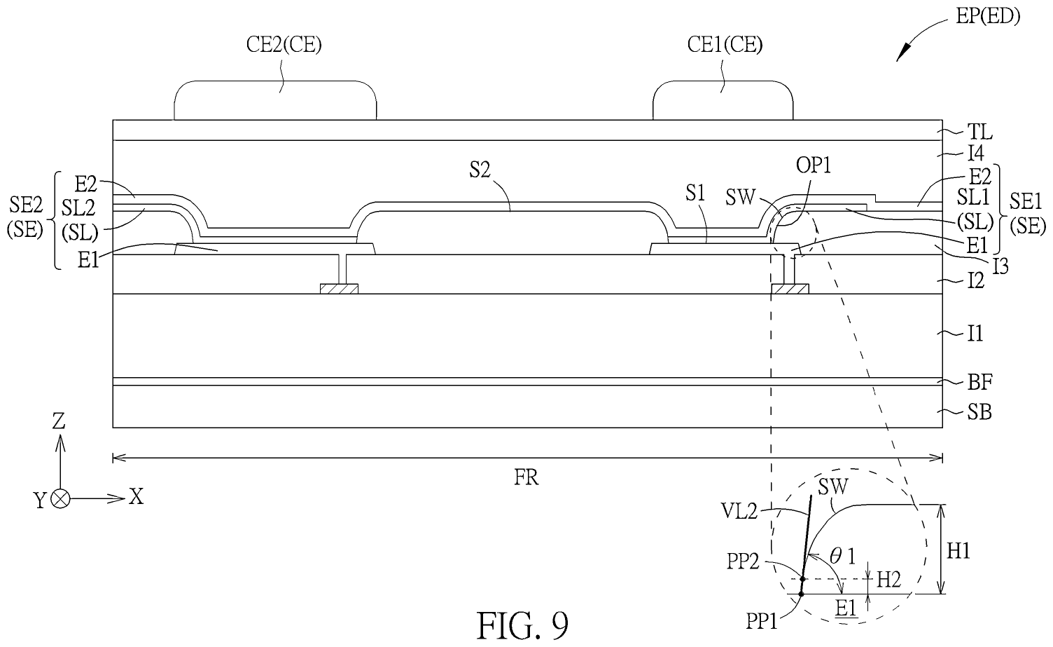

Referring to FIG. 9, FIG. 9 schematically illustrates a cross-sectional view of a functional region of an electronic panel according to a seventh embodiment of the present disclosure. In order to simplify the figure, FIG. 9 just shows some of the elements or the layers of the electronic panel EP corresponding to the functional region FR of the substrate SB, and the structures of the other elements or layers may refer to FIG. 2, which will not be redundantly described. As mentioned above, the electronic panel EP may include the insulating layer 13 disposed on the first electrode E1, wherein the insulating layer 13 may have the opening OP1, and the first semiconductor layer SL1 may enter the opening OP1 and be electrically connected to the first electrode E1 through the opening OP1. In the cross-sectional view of the electronic panel EP (that is, FIG. 9), the opening OP1 may be defined by the sidewall SW of the insulating layer 13, and the sidewall SW of the insulating layer 13 may have a taper θ1. The taper θ1 of the sidewall SW may for example be defined through the following way. First, as shown in FIG. 9, a first point PP1 on the sidewall SW of the insulating layer 13 in contact with the top surface S1 of the first electrode E1 may be defined at first. After that, a second point PP2 may be defined on the sidewall SW at the position corresponding to 0.1 times the height H1 of the insulating layer 13. Specifically, the second point PP2 on the sidewall SW may have a height H2, the height H2 may be defined as the vertical distance from the second point PP2 to the top surface S1 of the first electrode E1, wherein the height H2 may be 0.1 times the height H1. “The height H1 of the insulating layer 13” mentioned above may be the vertical distance from the top surface S2 of the insulating layer 13 to the top surface S1 of the first electrode E1, but not limited thereto. That is, the height H1 and the height H2 may be measured based on the top surface S1 of the first electrode E1, or the measurement reference surface of the height H1 and the height H2 may be the top surface S1 of the first electrode E1. After the first point PP1 and the second point PP2 are defined, a virtual line VL2 may be defined by the first point PP1 and the second point PP2, and the taper θ1 of the sidewall SW may be defined as the included angle between the virtual line VL2 and the top surface S1 of the first electrode E1 (or the included angle between the virtual line VL2 and horizontal direction (for example, the direction X)). According to the present embodiment, the taper θ1 of the sidewall SW may range from 30 degrees to 90 degrees (that is, 30°≤θ1≤90°), but not limited thereto. In some embodiments, the taper θ1 of the sidewall SW may range from 60 degrees to 90 degrees (that is, 60°≤θ1≤90°. In some embodiments, the taper θ1 of the sidewall SW may range from 75 degrees to 90 degrees (that is, 75°≤θ1≤90°). By making the taper θ1 of the sidewall SW of the insulating layer 13 within the above-mentioned range, large-angle light emitted from the semiconductor element SE may be reduced, thereby reducing the possibility that the light does not pass through the color conversion element CE and affects the display quality of the electronic panel EP.

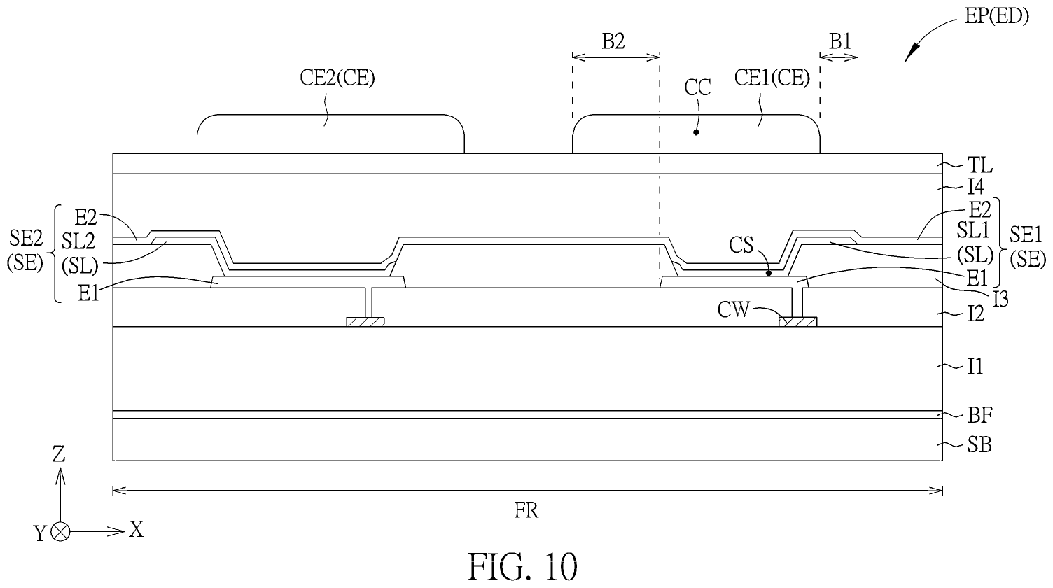

Referring to FIG. 10, FIG. 10 schematically illustrates a cross-sectional view of a functional region of an electronic panel according to an eighth embodiment of the present disclosure. In order to simplify the figure, FIG. 10 just shows some of the elements or the layers of the electronic panel EP corresponding to the functional region FR of the substrate SB, and the structures of the other elements or layers may refer to FIG. 2, which will not be redundantly described. According to the present embodiment, a semiconductor layer SL of a semiconductor element SE on the functional region FR of the substrate SB of the electronic panel EP may extend toward a direction, and the color conversion element CE corresponding to the semiconductor element SE may extend toward another direction, wherein the extending direction of the semiconductor layer SL may be different from the extending direction of the color conversion element CE. For example, as shown in FIG. 10, the first semiconductor layer SL1 of the first semiconductor element SE1 may extend toward the direction X, and the first color conversion element CE1 corresponding to the first semiconductor element SE1 may extend toward the direction −X, but not limited thereto. In some embodiments, the extending direction of the first semiconductor layer SL1 may be perpendicular to the extending direction 41 the first color conversion element CE1. In some embodiments, the first semiconductor layer SL1 may extend toward a direction, and the first color conversion element CE1 may extend toward another direction different from the direction, wherein the direction and the another direction may be any direction. Similarly, the extending direction of the second semiconductor layer SL2 of the second semiconductor element SE2 (for example, the direction −X) may be different from the extending direction (for example, the direction X) of the second color conversion element CE2 corresponding to the second semiconductor element SE2. Through the above-mentioned design, the center CS of the semiconductor layer SL of the semiconductor element SE disposed on the functional region FR may be deviated from the center CC of the color conversion element CE corresponding to the semiconductor element SE, and the range of the deviation distance may refer to the range of the first distance L1 mentioned above, which will not be redundantly described. In addition, in the cross-sectional view of the electronic panel EP of the present embodiment, the distance between the semiconductor layer SL and the color conversion element CE at a side of the semiconductor element SE may be different from the distance between the semiconductor layer SL and the color conversion element CE at another side of the semiconductor element SE. For example, as shown in FIG. 10, at the right side of the first semiconductor element SE1, the first semiconductor layer SL1 may protrude from the first color conversion element CE1, and a first distance B1 may be included between the side of the first color conversion element CE1 and the side of the first semiconductor layer SL1; and at the left side of the first semiconductor element SE1, the first color conversion element CE1 may protrude from the first semiconductor layer SL1, and a second distance B2 may be included between the side of the first color conversion element CE1 and the side of the first semiconductor layer SL1, wherein the first distance B1 may be different from the second distance B2, but not limited thereto. In some embodiments, the first distance B1 may be the same as the second distance B2. By making the semiconductor layer SL of a semiconductor element SE disposed on the functional region FR and the color conversion element CE corresponding to the semiconductor element SE respectively extend toward different directions, the arrangement irregularity of the layers or the elements corresponding to the functional region FR may increase, thereby reducing the possibility of diffraction of light in the functional region FR and affecting the photosensitive element.

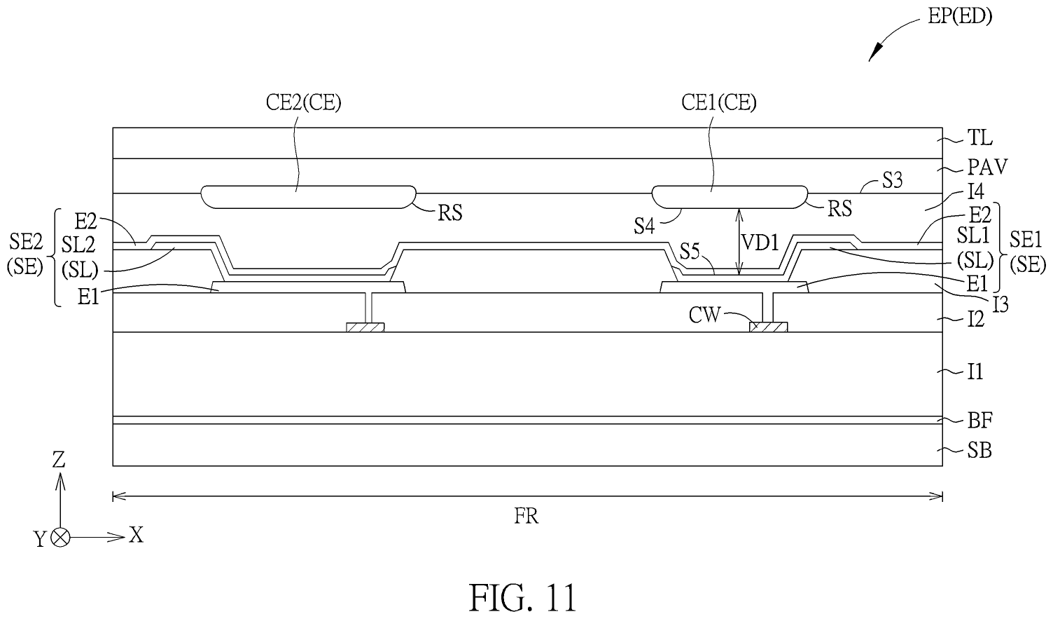

Referring to FIG. 11, FIG. 11 schematically illustrates a cross-sectional view of a functional region of an electronic panel according to a ninth embodiment of the present disclosure. In order to simplify the figure, FIG. 11 just shows some of the elements or the layers of the electronic panel EP corresponding to the functional region FR of the substrate SB, and the structures of the other elements or layers may refer to FIG. 2, which will not be redundantly described. In the present embodiment, the color conversion element CE may be disposed on the surface of the insulating layer 14 (that is, the above-mentioned encapsulation layer). For example, as shown in FIG. 11, the first color conversion element CE1 may be disposed on the surface (that is, the top surface S3) of the insulating layer 14, and the insulating layer 14 may be disposed between the first color conversion element CE1 and the first semiconductor element SE1. In detail, the insulating layer 14 has a top surface S3 facing the color conversion element CE (for example, the first color conversion element CE1), wherein the top surface S3 may include a concave RS, and the color conversion element CE may be disposed in the concave RS. “The color conversion element CE is disposed in the concave RS” described herein may include the condition that at least a portion of the color conversion element CE is filled into the concave RS. The electronic panel EP may further include an insulating layer PAV disposed on the color conversion element CE. The insulating layer PAV may be disposed on the insulating layer 14 and cover the color conversion element CE. The insulating layer PAV may include any suitable insulating material. According to the present embodiment, the concave RS may correspond to the semiconductor element SE, or in other words, the concave RS may at least partially overlap the semiconductor element SE in the top view direction of the electronic panel EP. Therefore, the color conversion element CE disposed in the concave RS may correspond to the semiconductor element SE. The concave RS may for example be formed by removing a portion of the insulating layer 14 corresponding to the semiconductor element SE. For example, the concave RS may for example be formed by removing a portion of the insulating layer 14 corresponding to the semiconductor element SE through half tone exposure technique or other suitable methods. In the present embodiment, each of the concaves RS of the top surface S3 of the insulating layer 14 may respectively correspond to a semiconductor element SE, and the color conversion elements CE may be disposed in the concaves RS to correspond to the semiconductor elements SE. For example, as shown in FIG. 11, the top surface S3 of the insulating layer 14 may include the concave RS overlapping the first semiconductor element SE1, and the first color conversion element CE1 may be disposed in the concave RS. By making the color conversion element CE disposed on the top surface S3 of the insulating layer 14 and/or making the color conversion element CE disposed in the concave RS, the vertical distance between the color conversion element CE and the semiconductor element SE to which the color conversion element CE corresponds may be reduced. Therefore, the possibility that the large-angle light emitted by the semiconductor element SE passes through the color conversion element CE may increase. Specifically, as shown in FIG. 11, a vertical distance VD1 may be included between the bottom surface S4 of the first color conversion element CE1 and the top surface S5 of the first semiconductor layer SL1 (or the portion of the first semiconductor layer SL1 in contact with the first electrode E1), wherein the vertical distance VD1 may range from 3 μm to 8 μm (that is, 3 μm≤VD1≤8 μm). In some embodiments, the vertical distance VD1 may range from 3 μm to 5 μm (that is, 3 μm≤VD1≤5 μm). The vertical distance between the bottom surface of the second color conversion element CE2 and the top surface of the second semiconductor layer SL2 may be the same as or different from the vertical distance VD1. It should be noted that the pattern designs of the semiconductor layer SL and the color conversion element CE of the present embodiment may refer to the contents in the above-mentioned embodiments, which is not limited to what is shown in FIG. 11.

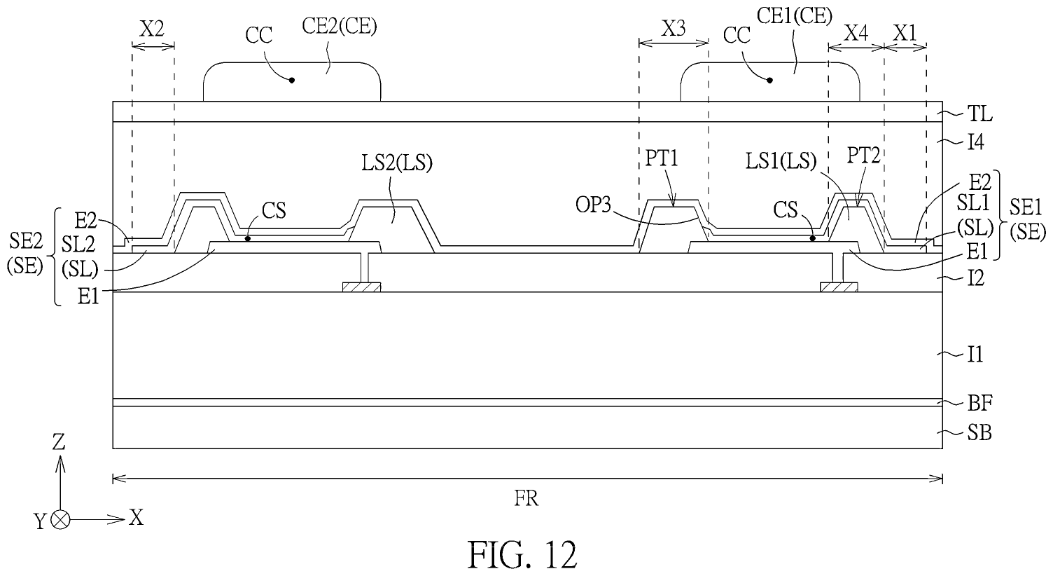

Referring to FIG. 12, FIG. 12 schematically illustrates a cross-sectional view of a functional region of an electronic panel according to a tenth embodiment of the present disclosure. In order to simplify the figure, FIG. 12 just shows some of the elements or the layers of the electronic panel EP corresponding to the functional region FR of the substrate SB, and the structures of the other elements or layers may refer to FIG. 2, which will not be redundantly described. According to the present embodiment, the electronic panel EP may include a light shielding pattern layer LS disposed on the insulating layer I2, wherein the light shielding pattern layer LS may be disposed corresponding to the semiconductor element SE. For example, the light shielding pattern layer LS may be disposed corresponding to the semiconductor element SE (that is, the first semiconductor element SE1 or the second semiconductor element SE2) disposed on the functional region FR, but not limited thereto. Specifically, although it is not shown in the figure, the light shielding pattern layer LS may surround the first electrode E1 of the semiconductor element SE disposed on the functional region FR in the top view direction of the electronic panel EP, but not limited thereto. For example, the light shielding pattern layer LS1 may surround the first electrode E1 of the first semiconductor element SE1, and the light shielding pattern layer LS2 may surround the first electrode E1 of the second semiconductor element SE2. In some embodiments, the light shielding pattern layer LS may partially be disposed on the first electrode E1. The light shielding pattern layer LS may define an opening OP3, and the semiconductor layer SL (for example, the first semiconductor layer SL1 and the second semiconductor layer SL2) may be disposed in the opening OP3 to be electrically connected to the first electrode E1. In other words, the light shielding pattern layer LS may serve as the pixel defining layer. The electronic panel EP of the present embodiment may not include the above-mentioned insulating layer 13, but not limited thereto. The light shielding pattern layer LS may include any suitable light shielding material, such as the black matrix layer BM mentioned above. The second electrode E2 may be conformally disposed on the semiconductor layer SL, the light shielding pattern layer LS and the insulating layer I2, but not limited thereto.

According to the present embodiment, the semiconductor layer SL of the semiconductor element SE disposed on the functional region FR may cross the light shielding pattern layer LS and extend outside the light shielding pattern layer LS. Specifically, the semiconductor layer SL may extend along the side surface and the top surface of the light shielding pattern layer LS and further extend to the outside of the light shielding pattern layer LS. In other words, at least a portion of the semiconductor layer SL may be located outside the light shielding pattern layer LS. For example, as shown in FIG. 12, the first semiconductor layer SL1 of the first semiconductor element SE1 may extend toward the direction X and cross the light shielding pattern layer LS1; and the second semiconductor layer SL2 of the second semiconductor element SE2 may extend toward the direction −X and cross the light shielding pattern layer LS2, but not limited thereto. Therefore, the center CS of the first semiconductor layer SL1 may be deviated from the center CC of the first color conversion element CE1, and the center CS of the second semiconductor layer SL2 may be deviated from the center CC of the second color conversion element CE2. By making the semiconductor layer SL disposed on the functional region FR extend toward a direction to cross the light shielding pattern layer LS, the irregularity of the layers corresponding to the functional region FR may increase, thereby reducing the possibility of diffraction of light in the functional region FR and affecting the photosensitive element. In the present embodiment, different semiconductor layers SL may extend toward different directions to cross different sides of the light shielding pattern layers LS.

In some embodiments, the widths of the portions of the semiconductor layers SL located outside the light shielding pattern layers LS may be different from each other. For example, as shown in FIG. 12, the portion of the first semiconductor layer SL1 located outside the light shielding pattern layer LS1 may have a width X1, and the portion of the second semiconductor layer SL2 located outside the light shielding pattern layer LS2 may have a width X2, wherein the width X1 may be different from the width X2. By making the widths of the portions of the semiconductor layers SL located outside the light shielding pattern layers LS different form each other, the irregularity of the layers corresponding to the functional region FR may increase.

In some embodiments, in the cross-sectional view of the electronic panel EP, the widths of the portions of the light shielding pattern layers LS respectively at two sides of the first electrode E1 may be different from each other. For example, as shown in FIG. 12, the light shielding pattern layer LS1 may include a portion PT1 on the left side of the first electrode E1 and a portion PT2 on the right side of the first electrode E1, the portion PT1 may have a width X3, and the portion PT2 may have a width X4, wherein the width X3 may be different from the width X4. The width X3 (or the width X4) may be defined as the maximum width of the portion PT1 (or the portion PT2) in the cross-sectional view of the electronic panel EP, but not limited thereto. In some embodiments, in the portions of the light shielding pattern layer LS respectively at two sides of the first electrode E1, the portion not crossed by the semiconductor layer SL may have a greater width. For example, as shown in FIG. 12, the first semiconductor layer SL1 may cross the portion PT2 of the light shielding pattern layer LS, and the width X4 of the portion PT2 may be less than the width X3 of the portion PT1, but not limited thereto. In some embodiments, the width X4 may be the same as the width X3. Through the above-mentioned design, the irregularity of the layers corresponding to the functional region FR may increase.

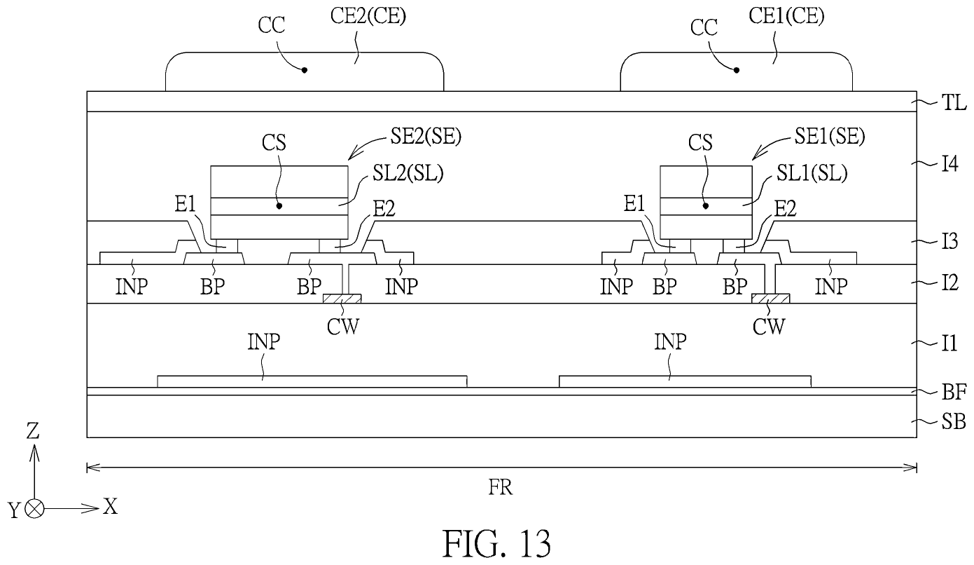

Referring to FIG. 13, FIG. 13 schematically illustrates a cross-sectional view of a functional region of an electronic panel according to an eleventh embodiment of the present disclosure. In order to simplify the figure, FIG. 13 just shows some of the elements or the layers of the electronic panel EP corresponding to the functional region FR of the substrate SB, and the structures of the other elements or layers may refer to FIG. 2, which will not be redundantly described. According to the present embodiment, the semiconductor element SE of the electronic panel EP may include an inorganic light emitting diode. In other words, as shown in FIG. 13, the first semiconductor element SE1 and the second semiconductor element SE2 disposed on the functional region FR may include inorganic light emitting diodes. The first semiconductor layer SL1 (or the second semiconductor layer SL2) of the first semiconductor element SE1 (or the second semiconductor element SE2) may be the light emitting layer of the inorganic light emitting diode. Therefore, the center CS of the first semiconductor layer SL1 (or the second semiconductor layer SL2) may be defined as the center of the light emitting layer of the inorganic light emitting diode. The first electrode E1 and/or the second electrode E2 of the first semiconductor element SE1 (or the second semiconductor element SE2) may be electrically connected to the connecting wire CW through the bonding pad BP. In the present embodiment, the semiconductor elements SE (for example, the first semiconductor element SE1 and the second semiconductor element SE2) disposed on the functional region FR may include inorganic light emitting diodes that emit light of different colors (for example, red, green, or blue), and the first color conversion element CE1 and the second color conversion element CE2 may include color filters, but not limited thereto. According to the present embodiment, the color conversion element CE corresponding to the semiconductor element SE disposed on the functional region FR may extend toward a direction, such that the center CC of the color conversion element CE may be deviated from the center CS of the semiconductor layer SL of the semiconductor element SE to which the color conversion element CE corresponds. For example, as shown in FIG. 13, the first color conversion element CE1 may extend toward the direction X, such that the center CC of the first color conversion element CE1 is deviated from the center CS of the first semiconductor layer SL1 (the light emitting layer) in the direction X; and the second color conversion element CE2 may extend toward the direction X, such that the center CC of the second color conversion element CE2 is deviated from the center CS of the second semiconductor layer SL2 (the light emitting layer) in the direction X. It should be noted that the extending direction of the first color conversion element CE1 may be different from the extending direction of the second color conversion element CE2, which is not limited to what is shown in FIG. 13.

In some embodiments, the electronic panel EP may further include the insulation pattern INP. In some embodiments, the insulation pattern INP may be disposed on the buffer layer BF and may correspond to the semiconductor element SE. The feature of the insulation pattern INP may refer to FIG. 2 or FIG. 7, which will not be redundantly described. In some embodiments, the insulation pattern INP may be disposed on the insulating layer I2 and adjacent to the bonding pad BP, and the feature thereof may refer to FIG. 8, which will not be redundantly described.

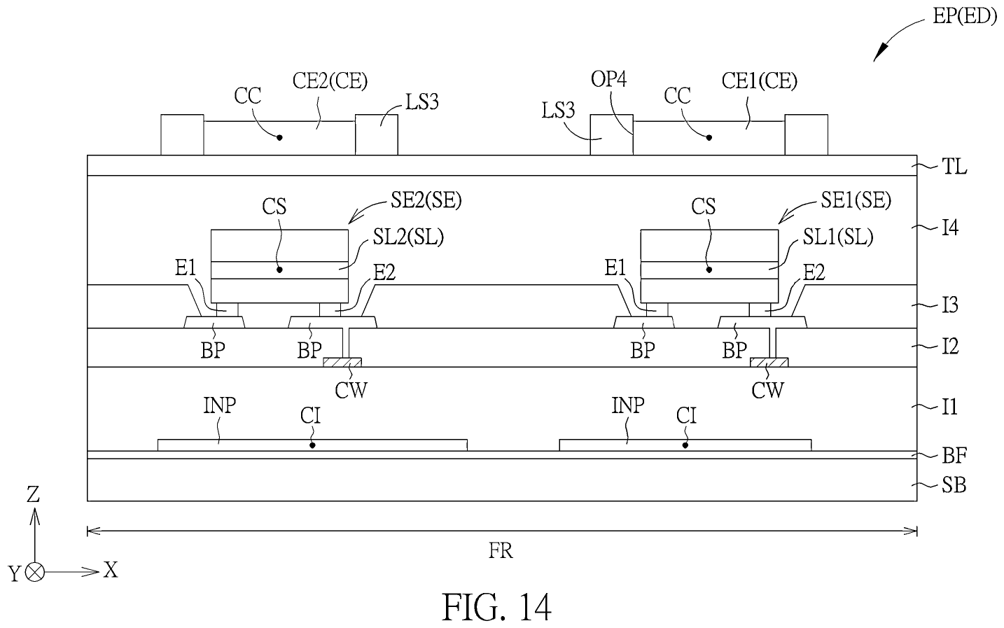

Referring to FIG. 14, FIG. 14 schematically illustrates a cross-sectional view of a functional region of an electronic panel according to a twelfth embodiment of the present disclosure. In order to simplify the figure, FIG. 14 just shows some of the elements or the layers of the electronic panel EP corresponding to the functional region FR of the substrate SB, and the structures of the other elements or layers may refer to FIG. 2, which will not be redundantly described. The semiconductor element SE of the present embodiment may include the inorganic light emitting diode, and the structure thereof may refer to FIG. 13 and related contents above, which will not be redundantly described. According to the present embodiment, as shown in FIG. 14, the electronic panel EP may include a light shielding pattern layer LS3 disposed corresponding to the functional region FR, wherein the light shielding pattern layer LS3 may be disposed to surround the color conversion element CE. Specifically, the light shielding pattern layer LS3 may defined an opening OP4, and the color conversion element CE may be disposed in the opening OP4. In the present embodiment, the semiconductor elements SE (for example, the first semiconductor element SE1 and the second semiconductor element SE2) disposed on the functional region FR may include inorganic light emitting diodes that emit light of the same color (for example, blue), and the first color conversion element CE1 and the second color conversion element CE2 may include suitable light converting materials such as quantum dots, but not limited thereto. Therefore, the light (for example, blue light) emitted from the first semiconductor element SE1 (or the second semiconductor element SE2) may be converted into the light of a desired color by the first color conversion element CE1 (or the second color conversion element CE2). By disposing the light shielding pattern layer LS3 surrounding the color conversion element CE, the large-angle light emitted from the semiconductor element SE may be reduced, thereby improving the display quality of the electronic panel EP.

In addition, in the present embodiment, the electronic panel EP may include the insulation pattern INP disposed between the semiconductor element SE and the functional region FR, wherein the insulation pattern INP may extend toward a direction, such that the center CI of the insulation pattern INP is deviated from the center CS of the semiconductor layer SL or the center CC of the color conversion element CE. Therefore, the irregularity of the layers corresponding to the functional region FR may increase. In the present embodiment, the center CS of the semiconductor layer SL may overlap the center CC of the color conversion element CE, but not limited thereto.

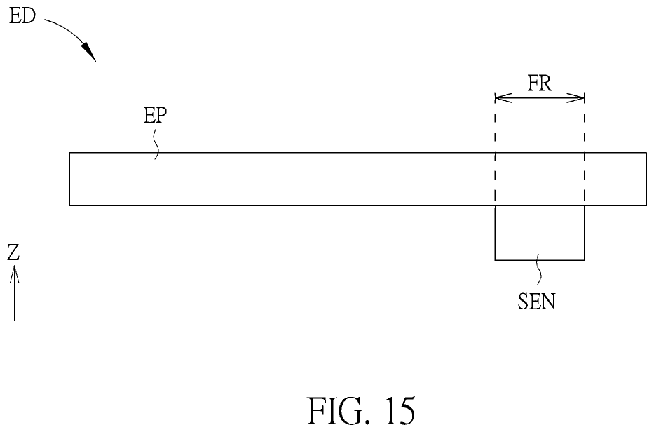

Referring to FIG. 15, FIG. 15 schematically illustrates a cross-sectional view of an electronic device according to an embodiment of the present disclosure. In order to simplify the figure, the structure of the electronic panel EP is shown as a single layer in FIG. 15. The electronic panel EP in the present embodiment may be the electronic panel EP described in any of the above-mentioned embodiments or combinations thereof. According to the present embodiment, as shown in FIG. 15, the electronic device ED may include the electronic panel EP and a sensing module SEN, wherein the sensing module SEN may be disposed corresponding to the functional region FR of the substrate (not shown) of the electronic panel EP. Specifically, the sensing module SEN is disposed under the functional region FR, but not limited thereto. In such condition, the sensing module SEN and the above-mentioned elements (such as the semiconductor element SE, the color conversion element CE, and the like) may respectively be disposed at two sides of the substrate. The sensing module SEN of the present embodiment may include a light sensing module, wherein the light sensing module may include any suitable photosensitive element that can receive visible light or non-visible light. For example, the light sensing module may include a camera, an infrared detector or other suitable elements. It should be noted that the sensing module SEN shown in FIG. 15 may include a single sensing element or a combination of multiple sensing elements. In other words, the electronic device ED may include various kinds of sensing elements, and these sensing elements may be disposed corresponding to the functional region FR. As mentioned above, since the layers corresponding to the functional region FR in the electronic panel EP may have a pattern design to increase the irregularity of arrangement of the layers, the possibility of diffraction of light in the functional region FR and affecting the sensing module SEN may be reduced, thereby improving the performance of sensing module SEN.

In summary, an electronic device is provided by the present disclosure, wherein the electronic device includes an electronic panel and a sensing module disposed corresponding to the functional region of the substrate of the electronic panel. By making the semiconductor layer or the color conversion element of the electronic panel corresponding to the functional region extend toward a direction or making the electronic panel include additional insulation pattern, the irregularity of the layers corresponding to the functional region may increase. Therefore, the possibility of diffraction of light in the functional region FR and affecting the photosensitive element may be reduced, thereby improving the performance of the sensing module.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic panel, comprising:
a substrate having a functional region capable of allowing a light to pass through;
a first semiconductor element disposed on the functional region, comprising a first electrode, a first semiconductor layer disposed on the first electrode, and a second electrode disposed on the first semiconductor layer; and
a first color conversion element disposed on the first semiconductor element and overlapped the first semiconductor layer,
wherein in a top view of the electronic panel, a center of the first color conversion element is deviated from a center of the first semiconductor layer.

2. The electronic panel according to claim 1, wherein the center of the first color conversion element is deviated from the center of the first semiconductor layer by a first distance ranged from 0.1 μm to 10.0 μm.

3. The electronic panel according to claim 1, wherein in the top view, a virtual line is defined by the center of the first semiconductor layer and the center of the first color conversion element, the virtual line crosses an edge of the first semiconductor layer at a first point and a second point and crosses an edge of the first color conversion element at a third point and a fourth point, and a second distance between the first point and the third point is different from a third distance between the second point and the fourth point.

4. The electronic panel according to claim 3, wherein the second distance ranges from 0.1 μm to 20.0 μm.

5. The electronic panel according to claim 3, wherein the third distance ranges from 0.1 μm to 20.0 μm.

6. The electronic panel according to claim 3, wherein the third point is located between the first point and the center of the first color conversion element.

7. The electronic panel according to claim 6, wherein the second point is located between the fourth point and the center of the first color conversion element.

8. The electronic panel according to claim 3, wherein the first point is located between the third point and the center of the first color conversion element, and the second point is located between the fourth point and the center of the first color conversion element.

9. The electronic panel according to claim 1, further comprising a second semiconductor element disposed on the functional region and a second color conversion element disposed on the second semiconductor element, wherein the second semiconductor element comprises a second semiconductor layer.

10. The electronic panel according to claim 9, wherein the center of the first color conversion element is deviated from the center of the first semiconductor layer in a first direction, a center of the second color conversion element is deviated from a center of the second semiconductor layer in a second direction, and the first direction is different from the second direction.

11. The electronic panel according to claim 9, wherein the center of the first color conversion element is deviated from the center of the first semiconductor layer by a first distance, a center of the second color conversion element is deviated from a center of the second semiconductor layer by a second distance, and the first distance is different from the second distance.

12. The electronic panel according to claim 1, further comprising an insulation pattern disposed between the functional region of the substrate and the first semiconductor element, wherein a center of the insulation pattern is deviated from the center of the first semiconductor layer.

13. The electronic panel according to claim 1, further comprising an insulation pattern disposed on the first electrode and adjacent to the first semiconductor layer.

14. The electronic panel according to claim 1, further comprising an insulating layer disposed on the first electrode and having an opening through which the first semiconductor layer is electrically connected to the first electrode, wherein in a cross-sectional view of the electronic panel, the opening is defined by a sidewall of the insulating layer, and a taper of the sidewall ranges from 30 degrees to 90 degrees.

15. The electronic panel according to claim 14, wherein the taper of the sidewall ranges from 60 degrees to 90 degrees.

16. The electronic panel according to claim 1, further comprising an encapsulation layer disposed between the first color conversion element and the first semiconductor element, wherein the encapsulation layer has a top surface facing the first color conversion element, and the top surface has a concave overlapped with the first semiconductor element.

17. The electronic panel according to claim 1, wherein the first semiconductor element is a light emitting element.

18. The electronic panel according to claim 1, wherein the first color conversion element is a color filter element.

19. An electronic device, comprising:
the electronic panel according to claim 1; and
a sensing module disposed under the functional region.

20. The electronic device according to claim 19, wherein the sensing module is an optical sensing module.
